(19) United States
(12) Patent Application Publication
(10) Pub. No.: US 2026/0133246 A1
(43) Pub. Date: May 14, 2026

(54) SEMICONDUCTOR DEVICE AND METHOD OF TESTING SEMICONDUCTOR DEVICE

(71) Applicant: Samsung Electronics Co., Ltd., Suwon-si (KR)

(72) Inventors: Seungmo NOH, Suwon-si (KR); Sang-In PARK, Suwon-si (KR)

(73) Assignee: Samsung Electronics Co., Ltd., Suwon-si (KR)

(21) Appl. No.: 19/275,351

(22) Filed: Jul. 21, 2025

(30) Foreign Application Priority Data
Nov. 13, 2024 (KR) 10-2024-0161465

(51) Int. Cl. G01R 31/28; G01R 31/317; G01R 31/3185

(52) U.S. Cl. CPC G01R 31/2853; G01R 31/31725; G01R 31/318525

(57) ABSTRACT

Disclosed is a semiconductor device including a first circuit component, a second circuit component, an interconnect configured to electrically connect the first circuit component and the second circuit component, and a test circuit connected between the first circuit component and the interconnect, and between the second circuit component and the interconnect, and the test circuit configured to measure a resistance component and a capacitance component of the interconnect.

### CROSS-REFERENCE TO RELATED APPLICATIONS

This application claims priority under 35 U.S.C. § 119 to Korean Patent Application No. 10-2024-0161465 filed on Nov. 13, 2024, in the Korean Intellectual Property Office, the disclosure of which is incorporated by reference herein in its entirety.

### BACKGROUND

Various example embodiments of inventive concepts described herein relate to a semiconductor device, and more particularly, relate to a test for measuring a resistance component and a capacitance component of an interconnect of a semiconductor device.

A semiconductor device may include various devices such as a memory device and a processor device. The semiconductor device may include interconnects for connecting circuit components. The interconnects of the semiconductor device may have self-resistance components and self-capacitance components.

While elements of the circuit components of the semiconductor device are scaled down, the influence of the resistance components and capacitance components of the interconnects of the semiconductor device on elements of circuit components of semiconductor devices is increasing. However, there is no device or method capable of independently measuring the resistance components and the capacitance components of the interconnects of the semiconductor device.

### SUMMARY

Various example embodiments of inventive concepts provide a semiconductor device providing a means for (or a semiconductor device that enables) independently measuring resistance components and capacitance components of interconnects of the semiconductor device, and a method of testing the semiconductor device.

In some example embodiments, a semiconductor device includes a first circuit component, a second circuit component, an interconnect configured to electrically connect the first circuit component and the second circuit component, and a test circuit connected between the first circuit component and the interconnect, and between the second circuit component and the interconnect, and the test circuit configured to measure a resistance component and a capacitance component of the interconnect.

In some example embodiments, a method of testing a semiconductor device including an interconnect connecting circuit components and a test circuit connected to the interconnect includes calculating a first time constant using a first capacitance of the test circuit and a reference resistor of an external test device, calculating a second time constant using a second capacitance of the test circuit and the reference resistor of the external test device, calculating a third time constant using the first capacitance of the test circuit and the interconnect, calculating a fourth time constant using the second capacitance of the test circuit and the interconnect, and calculating a resistance component of the interconnect based on the first time constant, the second time constant, the third time constant, and the fourth time constant.

In some example embodiments, a method of testing a semiconductor device including an interconnect connecting circuit components and a test circuit connected to the interconnect includes calculating a first time constant using a first resistor of the test circuit and a reference capacitance of an external test device, calculating a second time constant using a second resistor of the test circuit and the reference capacitance of the external test device, calculating a third time constant using the first resistor of the test circuit and the interconnect, calculating a fourth time constant using the second resistor of the test circuit and the interconnect, and calculating a capacitance component of the interconnect based on the first time constant, the second time constant, the third time constant, and the fourth time constant.

In some example embodiments, a test system to test a semiconductor device includes a test device including a reference resistor and a reference capacitance, and a semiconductor device including a first circuit component, a second circuit component, and interconnect configured to electrically connect the first circuit component and the second circuit component, and a test circuit connected to the first circuit component, the second circuit component, and the interconnect, wherein the test circuit is configured to measure a resistance component and a capacitance component of the interconnect using at least one of the reference resistor or the reference capacitance of the test device.

In some example embodiments, the test circuit is connected between the first circuit component and the interconnect, and between the second circuit component and the interconnect.

In some example embodiments, the test circuit is configured to sequentially measure the resistance component and the capacitance component.

In some example embodiments, the test circuit is configured to measure a first time constant based on the reference resistor and a first capacitance, measure a second time constant based on the reference resistor and a second capacitance, measure a third time constant based on the interconnect and the first capacitance, and measure a fourth time constant based on the interconnect and the second capacitance.

### BRIEF DESCRIPTION OF THE FIGURES

The above and other objects and features of the present inventive concepts will become apparent by describing in detail some example embodiments thereof with reference to the accompanying drawings.

FIG. 1 illustrates a test system of a semiconductor device according to some example embodiments.

FIG. 2 illustrates an interconnect and a test circuit according to some example embodiments.

FIG. 3 illustrates an example of a method in which a test circuit and a test device measure a first resistance component and a first capacitance component of an interconnect.

FIG. 4 illustrates a method in which a test circuit measures a first resistance component.

FIG. 5 illustrates an example in which a test operation is performed by a test circuit in a semiconductor device.

FIG. 6 illustrates an example of a half-life time constant.

FIG. 7 illustrates a method in which a test circuit measures a first resistance component.

FIG. 8 illustrates an example of a first circuit, a second circuit, and a third circuit according to some example embodiments.

FIG. 9 illustrates an example of a process in which a test circuit of FIG. 8 operates.

FIG. 10 illustrates a test system of a semiconductor device according to some example embodiments.

FIG. 11 illustrates an example of a method of implementing a test circuit according to some example embodiments.

FIG. 12 is a block diagram illustrating an electronic device capable of being a part of a system for fabrication of a semiconductor device according to some example embodiments.

FIG. 13 illustrates a semiconductor fabricating system according to some example embodiments.

FIG. 14 illustrates an example of weak points of semiconductor dies on a wafer.

FIG. 15 is a view for describing a semiconductor device according to some example embodiments.

FIG. 16 illustrates an example in which a semiconductor device is fabricated in a COP method.

### DETAILED DESCRIPTION

Below, some example embodiments of the present inventive concepts will be described in detail and clearly to such an extent that an ordinary one in the art may easily carry out the present inventive concepts.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof (e.g., structures, surfaces, directions, or the like), which may be referred to as being “perpendicular” or “parallel,” or the like with regard to other elements and/or properties thereof (e.g., structures, surfaces, directions, or the like) may be “perpendicular” or “parallel,” or the like or may be “substantially perpendicular” or “substantially parallel,” respectively, with regard to the other elements and/or properties element.

Elements and/or properties thereof (e.g., structures, surfaces, directions, or the like) that are “perpendicular” or “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “parallel” or “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

When the terms “approximately,” “about” or “substantially” are used in this specification in connection with a numerical value, it is intended that the associated numerical value includes a manufacturing or operational tolerance (e.g., ±10%) around the stated numerical value. Moreover, when the words “approximately,” “about” and “substantially” are used in connection with geometric shapes, it is intended that precision of the geometric shape is not required but that latitude for the shape is within the scope of the disclosure. Further, regardless of whether numerical values or shapes are modified as “approximately,” “about” or “substantially,” it will be understood that these values and shapes should be construed as including a manufacturing or operational tolerance (e.g., ±10%) around the stated numerical values or shapes.

It will be understood that elements and/or properties thereof may be recited herein as being “the same” or “equal” as other elements, and it will be further understood that elements and/or properties thereof recited herein as being “the same” as, “equal” to, or “identical” to other elements may be “the same” as, “equal” to, or “identical” to or “substantially the same” as, “substantially equal” to, or “substantially identical” to the other elements and/or properties thereof. Elements and/or properties thereof that are “substantially the same” as, “substantially equal” to, or “substantially identical” to other elements and/or properties thereof will be understood to include elements and/or properties thereof that are the same as, equal to, or identical to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

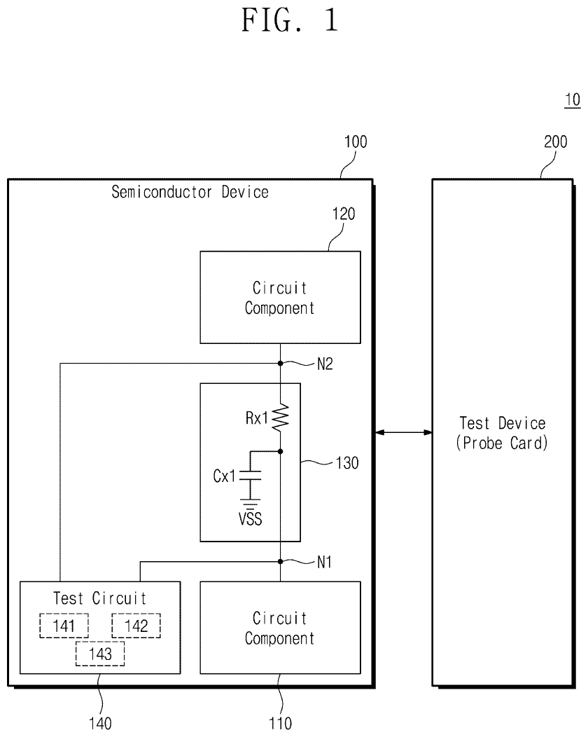

FIG. 1 illustrates a test system 10 of a semiconductor device according to some example embodiments. Referring to FIG. 1, the test system 10 may include a semiconductor device 100 and a test device 200.

The semiconductor device 100 may include various semiconductor devices such as a memory device and a processor device. The test device 200 may include various means for (or the test device 200 may enable) testing the semiconductor device 100, for example, may include a probe card.

The semiconductor device 100 may include a first circuit component 110, a second circuit component 120, an interconnect 130, and a test circuit 140. The first circuit component 110 and the second circuit component 120 may be configured to perform operations suitable for design purposes of the semiconductor device 100. The interconnect 130 may be configured to electrically connect the first circuit component 110 and the second circuit component 120.

The interconnect 130 may include a first resistance component Rx1 and a first capacitance component Cx1. For example, the first resistance component Rx1 may be based on a parasitic resistor of the interconnect 130. The first resistance component Rx1 may be modeled as a resistor connected in series between the first circuit component 110 and the second circuit component 120. The first capacitance component Cx1 may be based on a parasitic capacitance of the interconnect 130. The first capacitance component Cx1 may be modeled as a capacitor connected in parallel with a ground node, to which a ground voltage VSS is supplied, between the first circuit component 110 and the second circuit component 120.

In some example embodiments, the interconnect 130 may include a through silicon via (TSV), or a vertical line such as a contact.

The test circuit 140 may be connected between a first node N1 and a second node N2. The first node N1 may be between the first circuit component 110 and the interconnect 130 and the second node N2 may be between the second circuit component 120 and the interconnect 130. The test circuit 140 may sequentially measure the first resistance component Rx1 and the first capacitance component Cx1, respectively.

The test circuit 140 may include a first circuit 141, a second circuit 142, and a third circuit 143. The first circuit 141 may support the measurement of the first capacitance component Cx1 of the interconnect 130. For example, the first circuit 141 may amplify a signal associated with the first capacitance component Cx1 of the interconnect 130 by providing an additional resistor to the first resistance component Rx1 of the interconnect 130. The first circuit 141 may support to measure the first capacitance component Cx1 more accurately by amplifying the signal associated with the first capacitance component Cx1.

The second circuit 142 may support the measurement of the first resistance component Rx1 of the interconnect 130. For example, the second circuit 142 may amplify a signal associated with the first resistance component Rx1 of the interconnect 130 by providing an additional capacitance to the first capacitance component Cx1 of the interconnect 130. The second circuit 142 may support to measure the first resistance component Rx1 more accurately by amplifying the signal associated with the first resistance component Rx1.

The third circuit 143 may measure the signal associated with the first capacitance component Cx1 and the signal associated with the first resistance component Rx1 and may provide a measurement result to the test device 200.

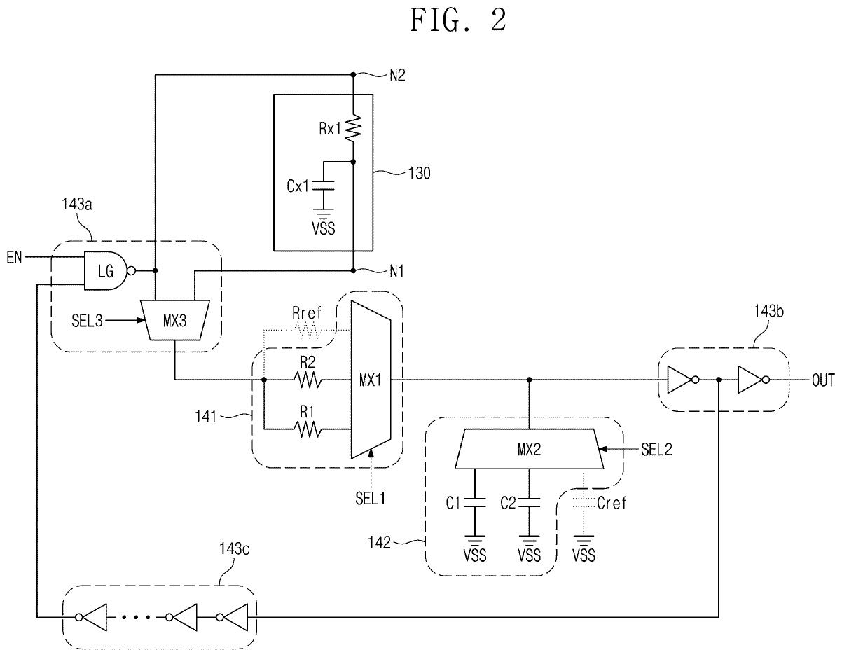

FIG. 2 illustrates the interconnect 130 and the test circuit 140 according to some example embodiments. Referring to FIGS. 1 and 2, the first circuit 141 may include a first multiplexer MX1, a first resistor R1 connected to a first input of the first multiplexer MX1, and a second resistor R2 connected to a second input of the first multiplexer MX1. A resistance value of the first resistor R1 may be different from a resistance value of the second resistor R2.

The first multiplexer MX1 may further include a third input. The third input of the first multiplexer MX1 may be connected to the test device 200. The test device 200 may provide a reference resistor Rref to the third input of the first multiplexer MX1. The reference resistor Rref may be an external resistor provided by the test device 200 and thus may have higher accuracy than the first resistor R1 and the second resistor R2 provided within the semiconductor device 100.

First ends of the first resistor R1, the second resistor R2, and the reference resistor Rref may be respectively connected to the first input, the second input, and the third input of the first multiplexer MX1, and second ends of the first resistor R1, the second resistor R2, and the reference resistor Rref may be connected in common to an output of a third multiplexer MX3. The first multiplexer MX1 may electrically connect one of the first resistor R1, the second resistor R2, and the reference resistor Rref to an output node in response to a first selection signal SEL1. In some example embodiments, the first selection signal SEL1 may be provided from the test device 200 or may be provided from an internal test control circuit of the semiconductor device 100, for example, a built-in self-test (BIST) circuit.

The second circuit 142 may include a second multiplexer MX2, a first capacitor C1 connected to a first input of the second multiplexer MX2, and a second capacitor C2 connected to a second input of the second multiplexer MX2. A capacitance of the first capacitor C1 may be different from a capacitance of the second capacitor C2.

The second multiplexer MX2 may further include a third input. The third input of the second multiplexer MX2 may be connected to the test device 200. The test device 200 may provide a reference capacitor Cref to the third input of the second multiplexer MX2. The reference capacitor Cref may be an external capacitor provided by the test device 200 and thus may have a higher accuracy than the first capacitor C1 and the second capacitor C2 provided within the semiconductor device 100.

First ends of the first capacitor C1, the second capacitor C2, and the reference capacitor Cref may be connected to the second multiplexer MX2, and second ends of the first capacitor C1, the second capacitor C2, and the reference capacitor Cref may be connected to the ground node to which the ground voltage VSS is applied. An output node of the second multiplexer MX2 may be connected to the output node of the first multiplexer MX1. The second multiplexer MX2 may electrically connect one of the first capacitor C1, the second capacitor C2, and the reference capacitor Cref to the output node in response to a second selection signal SEL2. In some example embodiments, the second selection signal SEL2 may be provided from the test device 200 or may be provided from the internal test control circuit of the semiconductor device 100, for example, the built-in self-test (BIST) circuit.

The third circuit 143 may include a 3a-th circuit 143a, a 3b-th circuit 143b, and a 3c-th circuit 143c. The 3a-th circuit 143a may receive a test enable signal EN. In some example embodiments, the test enable signal EN may be provided from the test device 200 or may be provided from the internal test control circuit of the semiconductor device 100, for example, the built-in self-test (BIST) circuit.

The 3a-th circuit 143a may include a logic gate LG and the third multiplexer MX3. A first input of the logic gate LG may receive the test enable signal EN, and a second input of the logic gate LG may receive an output of the 3c-th circuit 143c. The logic gate LG may perform a NAND operation on signals of the first input and the second input. An output signal of the logic gate LG may be provided to the third multiplexer MX3 and may be provided to the interconnect 130 through the second node N2.

The third multiplexer MX3 may include a first input receiving the output signal of the logic gate LG and a second input receiving the output signal of the logic gate LG through the second node N2, the interconnect 130, and the first node N1. The third multiplexer MX3 may transfer one of the signals of the first input and the second input to the output node in response to a third selection signal SEL3. In some example embodiments, the third selection signal SEL3 may be provided from the test device 200 or may be provided from the internal test control circuit of the semiconductor device 100, for example, the built-in self-test (BIST) circuit. The output node of the third multiplexer MX3 may be connected to the first circuit 141.

The 3b-th circuit 143b may provide an output signal of a node, to which the first circuit 141 and the second circuit 142 are connected, to the test device 200. The 3b-th circuit 143b may include at least two (e.g., an even number of) inverters for buffering a signal. The 3b-th circuit 143b may output an output signal OUT to the test device 200.

The 3c-th circuit 143c may include a plurality of delay units, for example, a plurality of (e.g., an odd number of) inverters. In some example embodiments, when the test device 200 is a test device of a wafer level or a package level, the operating frequency of the test device 200 may be lower than the operating frequency of the semiconductor device 100. The 3c-th circuit 143c may be configured to fit the operating speed of the test circuit 140 to the operating frequency of the test device 200. A delay amount of the 3c-th circuit 143c, for example, the number of delay units of the 3c-th circuit 143c may be determined depending on (or based on) the operating frequency of the test device 200.

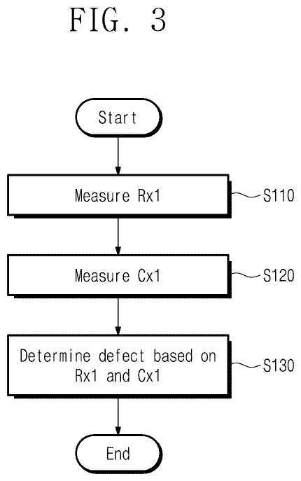

FIG. 3 illustrates an example of a method in which the test circuit 140 and the test device 200 measure the first resistance component Rx1 and the first capacitance component Cx1 of the interconnect 130. Referring to FIGS. 1, 2, and 3, in operation S110, the test circuit 140 may measure the first resistance component Rx1. In operation S120, the test circuit 140 may measure the first capacitance component Cx1. The test circuit 140 may provide information about the first resistance component Rx1 and the first capacitance component Cx1 to the test device 200.

In some example embodiments, the test circuit 140 may perform a test operation of measuring the first resistance component Rx1 and the first capacitance component Cx1 under support of the test device 200. In some example embodiments, the test circuit 140 may measure the first capacitance component Cx1 and may then measure the first resistance component Rx1. The test circuit 140 may obtain accurate information about a feature of the interconnect 130 by individually measuring the first resistance component Rx1 and the first capacitance component Cx1.

In operation S130, the test device 200 may determine whether the semiconductor device 100 is defective, based on the first resistance component Rx1 and the first capacitance component Cx1. For example, when the first resistance component Rx1 or the first capacitance component Cx1 is greater than a threshold value, the test device 200 may determine that the semiconductor device 100 is defective. For example, the threshold value may be determined based on a level at which the first resistance component Rx1 or the first capacitance component Cx1 causes an abnormal operation in the first circuit component 110 or the second circuit component 120.

In some example embodiments, when it is determined that the semiconductor device 100 is defective, the semiconductor device 100 may be discarded or may be used as a product for down-clock. In some example embodiments, when it is determined that the semiconductor device 100 is not defective, the semiconductor device 100 may be used as a good product. In some example embodiments, based on determining whether a resistance component (e.g., first resistance component Rx1) or a capacitance component (e.g., first capacitance component Cx1) in a semiconductor device (e.g., semiconductor device 100) is defective, it may be determined that the semiconductor device is a defective product or a good product. Thereby, functionality of a manufacturing system and/or a manufacturing process of semiconductor devices may be improved, and the technical field of manufacturing semiconductor devices may be improved. Additionally or alternatively, according to some example embodiments, it may be possible to reduce or prevent incorrect pass/fail judgment of a semiconductor device (e.g., semiconductor device 100) due to including a defective resistance component and/or a defective capacitance component. Depending on (or based on) the judgement results, passed semiconductor devices may be sorted out as good products and proceed to other subsequent processes (e.g., subsequent manufacturing processes), and failed semiconductor devices may be discarded, reworked or refurbished, or downgraded.

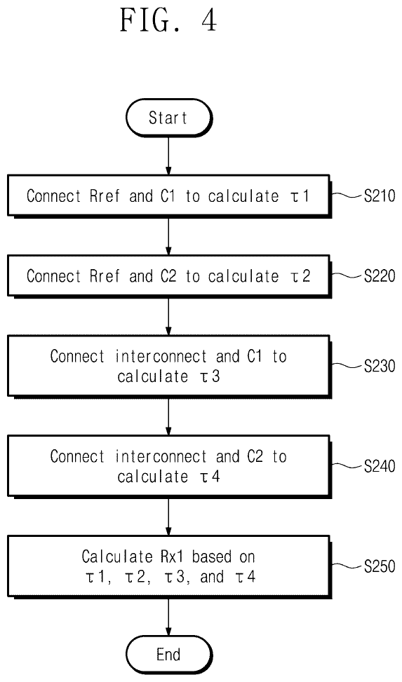

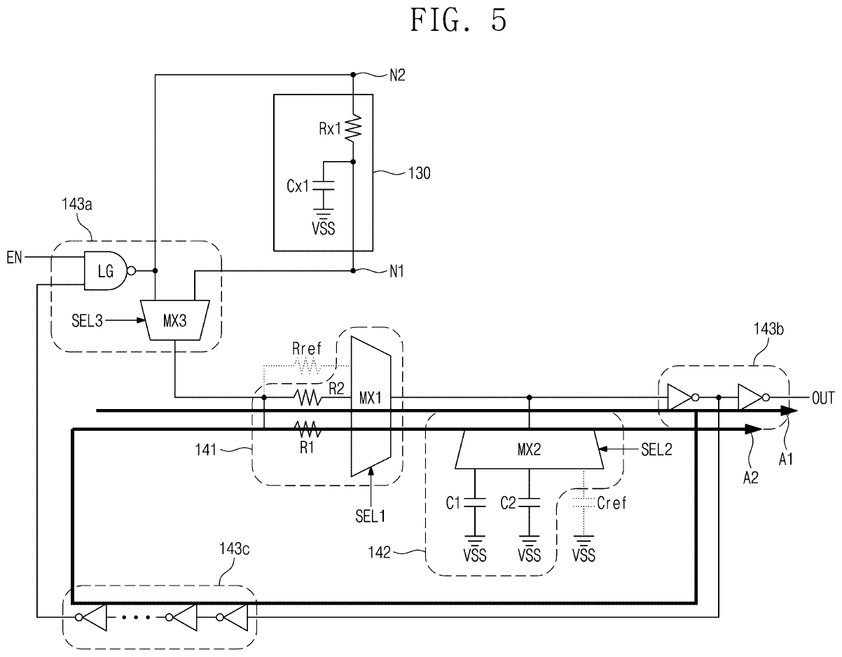

FIG. 4 illustrates a method in which the test circuit 140 measures the first resistance component Rx1. FIG. 5 illustrates an example in which the test operation is performed by the test circuit 140 in the semiconductor device 100. Referring to FIGS. 4 and 5, in operation S210, the test circuit 140 may calculate a first time constant τ1 by using the reference resistor Rref and the first capacitor C1.

For example, the third multiplexer MX3 of the 3a-th circuit 143a may output the output signal of the logic gate LG in response to the third selection signal SEL3. The first multiplexer MX1 of the first circuit 141 may receive the output signal of the third multiplexer MX3 through the reference resistor Rref in response to the first selection signal SEL1. The second multiplexer MX2 of the second circuit 142 may electrically connect the first capacitor C1 and the output node of the first multiplexer MX1 in response to the second selection signal SEL2.

As marked by a first arrow A1 of FIG. 5, the 3a-th circuit 143a may receive the test enable signal EN transitioning from the low level to the high level. The test enable signal EN may be transferred to the 3b-th circuit 143b through the first circuit 141 and the second circuit 142. The 3b-th circuit 143b may output the output signal OUT transitioning from the low level to the high level in response to the test enable signal EN.

As marked by a second arrow A2 of FIG. 5, the 3b-th circuit 143b may output an inverse signal of the output signal OUT to the 3c-th circuit 143c. The 3c-th circuit 143c may delay the inverse signal of the output signal OUT so as to be transferred to the logic gate LG of the 3a-th circuit 143a. In some example embodiments, when the output signal of the 3b-th circuit 143b transitions from the low level to the high level, the output signal of the 3a-th circuit 143a may transition from the high level to the low level.

As the output signal of the logic gate LG transitions from the high level to the low level, the output signals of the 3a-th circuit 143a and the 3b-th circuit 143b may also transition from the high level to the low level. A time at which the output signals of the 3a-th circuit 143a and the 3b-th circuit 143b transition from the high level to the low level may be based on a time constant defined by the first circuit 141 and the second circuit 142.

In some example embodiments, because the 3b-th circuit 143b includes inverters, when the output signals of the 3a-th circuit 143a and the 3b-th circuit 143b reach half the high level, the output signal OUT may transition from the high level to the low level. For example, the timing at which the output signal OUT transitions from the high level to the low level may indicate a half-life time constant of the 3a-th circuit 143a and the 3b-th circuit 143b.

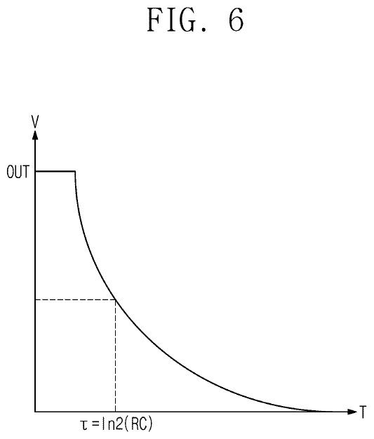

FIG. 6 illustrates an example of a half-life time constant. In FIG. 6, the horizontal axis represents a time “T”, and the vertical axis represents a voltage “V”. The time constant t indicating the time during which the level of the output signal OUT decrease to a half level may be determined by Equation 1 below.

$$τ = ln 2 ( RC ) \qquad [ Equation l ]$$

Equation 2 below may indicate the first time constant τ1 measured in operation S210 based on Equation 1 above.

$$τ 1 = ln 2 \cdot ( Rref \cdot C 1 ) + δ {V}_{T} \cdot δ {L}_{g} \cdot δ ETC \qquad [ Equation 2 ]$$

In Equation 2 above, δV_{T} may indicate a change in threshold voltages of transistors, for example, transistors of the test circuit 140 due to the process variations, δL_{g} may indicate a change in a size (e.g., a width or length) of gates of transistors, for example, transistors of the test circuit 140 due to the process variations, and δETC may indicate any other change of transistors, for example, transistors of the test circuit 140 due to the process variations.

The test device 200 may provide the test enable signal EN to the test circuit 140 and may then calculate the first time constant τ1 based on a time at which the output signal OUT transitions from the high level to the low level after the output signal OUT transitions from the low level to the high level.

In operation S220, the test circuit 140 may calculate a second time constant τ2 by using the reference resistor Rref and the second capacitor C2. The process of calculating the second time constant τ2 may be the same as the process of calculating the first time constant τ1 except that the second capacitor C2 is used. Equation 3 below may indicate the second time constant τ2 measured in operation S220 based on Equation 1 above.

$$\text{?} \qquad [ Equation 3 ]$$

$$\text{?} \text{indicates text missing or illegible when filed}$$

In operation S230, the test circuit 140 may calculate a third time constant τ3 by using the interconnect 130 and the first capacitor C1. The process of calculating the third time constant τ3 may be the same as the process of calculating the first time constant τ1 except that interconnect 130 is used. Equation 4 below may indicate the third time constant τ3 measured in operation S230 based on Equation 1 above.

$$τ 3 = ln 2 \cdot ( Rx 1 \cdot C 1 ) + δ {V}_{T} \cdot δ {L}_{g} \cdot δ ETC \qquad [ Equation 4 ]$$

In operation S240, the test circuit 140 may calculate a fourth time constant τ4 by using the interconnect 130 and the second capacitor C2. The process of calculating the fourth time constant τ4 may be the same as the process of calculating the third time constant τ3 except that the second capacitor C2 is used. Equation 5 below may indicate the fourth time constant τ4 measured in operation S240 based on Equation 1 above.

$$τ 4 = ln 2 \cdot ( Rx 1 \cdot C 2 ) + δ {V}_{T} \cdot δ {L}_{g} \cdot δ ETC \qquad [ Equation 5 ]$$

In operation S250, the test device 200 may calculate the first resistance component Rx1 based on the first time constant τ1, the second time constant τ2, the third time constant τ3, and the fourth time constant τ4. For example, the test device 200 may calculate the first resistance component Rx1 of the interconnect 130 based on Equation 6 below.

$$Cx 1 ≅ \frac{τ 4 - τ 3}{τ 2 - τ 1} = \frac{ln 2 \cdot ( Rx 1 \cdot C 2 ) - ln 2 \cdot ( Rx 1 \cdot C 1 )}{ln 2 \cdot ( Rref \cdot C 2 ) - ln 2 \cdot ( Rref \cdot C 1 )} = \frac{ln 2 \cdot ( Rx 1 ( C 2 - C 1 ) )}{ln 2 \cdot ( Rref ( C 2 - C 1 ) )} = \frac{Rx 1}{Rref} \qquad [ Equation 6 ]$$

The test device 200 may calculate the first resistance component Rx1 of the interconnect 130 by multiplying a calculation result of Equation 6 above and the resistance value of the reference resistor Rref together.

In the test operation, the test circuit 140 may amplify values of the first time constant τ1, the second time constant τ2, the third time constant τ3, and the fourth time constant τ4 by using the first capacitor C1 and the second capacitor C2. Accordingly, the accuracy of the first resistance component Rx1 of the interconnect 130 may be improved.

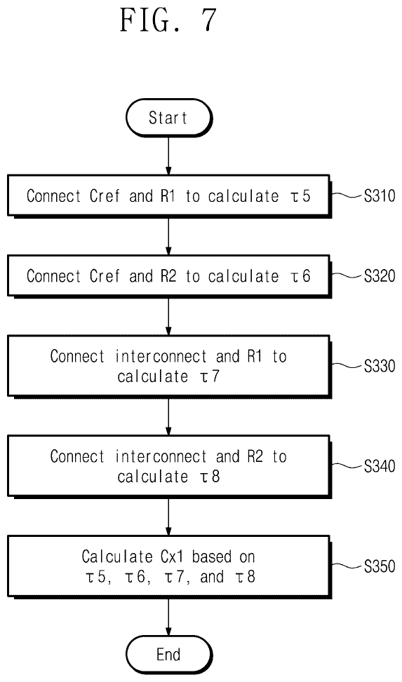

FIG. 7 illustrates a method in which the test circuit 140 measures the first resistance component Rx1. Referring to FIGS. 5 and 7, in operation S310, the test circuit 140 may calculate a fifth time constant τ5 by using the reference capacitor Cref and the first resistor R1.

For example, the third multiplexer MX3 of the 3a-th circuit 143a may output the output signal of the logic gate LG in response to the third selection signal SEL3. The first multiplexer MX1 of the first circuit 141 may receive the output signal of the third multiplexer MX3 through the first resistor R1 in response to the first selection signal SEL1. The second multiplexer MX2 of the second circuit 142 may electrically connect the reference capacitor Cref and the output node of the first multiplexer MX1 in response to the second selection signal SEL2.

As marked by the first arrow A1 of FIG. 5, the 3a-th circuit 143a may receive the test enable signal EN transitioning from the low level to the high level. The test enable signal EN may be transferred to the 3b-th circuit 143b through the first circuit 141 and the second circuit 142. The 3b-th circuit 143b may output the output signal OUT transitioning from the low level to the high level in response to the test enable signal EN.

As marked by the second arrow A2 of FIG. 5, the 3b-th circuit 143b may output an inverse signal of the output signal OUT to the 3c-th circuit 143c. The 3c-th circuit 143c may delay the inverse signal of the output signal OUT so as to be transferred to the logic gate LG of the 3a-th circuit 143a. In some example embodiments, when the output signal of the 3b-th circuit 143b transitions from the low level to the high level, the output signal of the 3a-th circuit 143a may transition from the high level to the low level.

As the output signal of the logic gate LG transitions from the high level to the low level, the output signals of the 3a-th circuit 143a and the 3b-th circuit 143b may also transition from the high level to the low level. A time at which the output signals of the 3a-th circuit 143a and the 3b-th circuit 143b transition from the high level to the low level may be based on a time constant defined by the first circuit 141 and the second circuit 142.

In some example embodiments, because the 3b-th circuit 143b includes inverters, when the output signals of the 3a-th circuit 143a and the 3b-th circuit 143b reach half the high level, the output signal OUT may transition from the high level to the low level. For example, the timing at which the output signal OUT transitions from the high level to the low level may indicate a half-life time constant of the 3a-th circuit 143a and the 3b-th circuit 143b.

Equation 7 below may indicate the fifth time constant τ5 measured in operation S310 based on Equation 1 above.

$$τ 5 = ln 2 \cdot ( R 1 \cdot C ref ) + δ {V}_{T} \cdot δ {L}_{g} \cdot δ ETC \qquad [ Equation 7 ]$$

In Equation 7 above, δV_{T} may indicate a change in threshold voltages of transistors, for example, transistors of the test circuit 140 due to the process variations, δL_{g} may indicate a change in a size (e.g., a width or length) of gates of transistors, for example, transistors of the test circuit 140 due to the process variations, and δETC may indicate any other change of transistors, for example, transistors of the test circuit 140 due to the process variations.

The test device 200 may provide the test enable signal EN to the test circuit 140 and may then calculate the fifth time constant τ5 based on a time at which the output signal OUT transitions from the high level to the low level after the output signal OUT transitions from the low level to the high level.

In operation S320, the test circuit 140 may calculate a sixth time constant τ6 by using the second resistor R2 and the reference capacitor Cref. The process of calculating the sixth time constant τ6 may be the same as the process of calculating the fifth time constant τ5 except that the second resistor R2 is used. Equation 8 below may indicate the sixth time constant τ6 measured in operation S320 based on Equation 1 above.

$$τ 6 = ln 2 \cdot ( R 2 \cdot C ref ) + δ {V}_{T} \cdot δ {L}_{g} \cdot δ ETC \qquad [ Equation 8 ]$$

In operation S330, the test circuit 140 may calculate a seventh time constant τ7 by using the interconnect 130 and the first resistor R1. The process of calculating the seventh time constant τ7 may be the same as the process of calculating the fifth time constant τ5 except that interconnect 130 is used. Equation 9 below may indicate the seventh time constant τ7 measured in operation S330 based on Equation 1 above.

$$τ 7 = ln 2 \cdot ( R 1 \cdot Cx 1 ) + δ {V}_{T} \cdot δ {L}_{g} \cdot δ ETC \qquad [ Equation 9 ]$$

In operation S340, the test circuit 140 may calculate an eighth time constant τ8 by using the interconnect 130 and the second resistor R2. The process of calculating the eighth time constant τ8 may be the same as the process of calculating the seventh time constant τ7 except that the second resistor R2 is used. Equation 10 below may indicate the eighth time constant τ8 measured in operation S340 based on Equation 1 above.

$$τ 8 = ln 2 \cdot ( R 2 \cdot Cx 1 ) + δ {V}_{T} \cdot δ {L}_{g} \cdot δ ETC \qquad [ Equation 10 ]$$

In operation S350, the test device 200 may calculate the first capacitance component Cx1 based on the fifth time constant τ5, the sixth time constant τ6, the seventh time constant τ7, and the eighth time constant τ8. For example, the test device 200 may calculate the first capacitance component Cx1 of the interconnect 130 based on Equation 11 below.

$$Rx 1 ≅ \frac{τ 8 - τ 7}{τ 6 - τ 5} = \frac{ln 2 \cdot ( Cx 1 \cdot R 2 ) - ln 2 \cdot ( Cx 1 \cdot R 1 )}{ln 2 \cdot ( Cref \cdot R 2 ) - ln 2 \cdot ( Cref \cdot R 1 )} = \frac{ln 2 \cdot ( Cx 1 ( R 2 - R 1 ) )}{ln 2 \cdot ( Cref ( R 2 - R 1 ) )} = \frac{Cx 1}{Cref} \qquad [ Equation 11 ]$$

The test device 200 may calculate the first capacitance component Cx1 of the interconnect 130 by multiplying a calculation result of Equation 11 above and the capacitance value of the reference capacitor Cref together.

In the test operation, the test circuit 140 may amplify values of the fifth time constant τ5, the sixth time constant τ6, the seventh time constant τ7, and the eighth time constant τ8 by using the first resistor R1 and the second resistor R2. Accordingly, the accuracy of the first capacitance component Cx1 of the interconnect 130 may be improved.

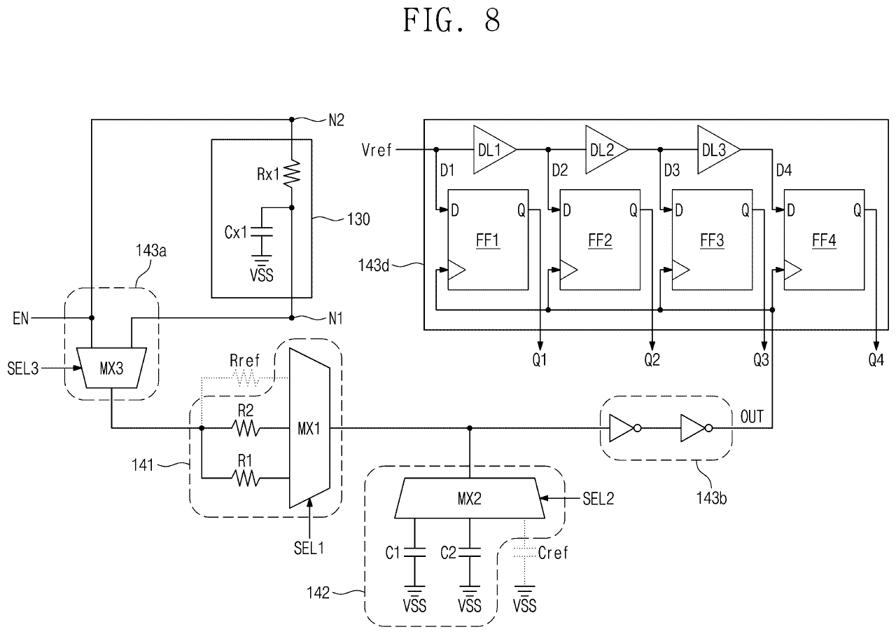

FIG. 8 illustrates an example of the first circuit 141, the second circuit 142, and the third circuit 143 according to some example embodiments. Referring to FIGS. 1 and 8, the first circuit 141 may include the first multiplexer MX1, the first resistor R1 connected to the first input of the first multiplexer MX1, and the second resistor R2 connected to the second input of the first multiplexer MX1. The third input of the first multiplexer MX1 may be connected to the reference resistor Rref of the test device 200. The second circuit 142 may include the second multiplexer MX2, the first capacitor C1 connected to the first input of the second multiplexer MX2, and the second capacitor C2 connected to the second input of the second multiplexer MX2. The third input of the second multiplexer MX2 may be connected to the reference capacitor Cref of the test device 200.

Configurations and operations of the first circuit 141 and the second circuit 142 may be the same as those of the first circuit 141 and the second circuit 142 described with reference to FIG. 2. Thus, additional description will be omitted to avoid redundancy.

The third circuit 143 may include the 3a-th circuit 143a, the 3b-th circuit 143b, and a 3d-th circuit 143d. The 3a-th circuit 143a may include the third multiplexer MX3. A configuration and an operation of the 3a-th circuit 143a may be the same as those of the 3a-th circuit 143a of FIG. 2 except that the logic gate LG is excluded. Thus, additional description will be omitted to avoid redundancy. The test enable signal EN may be transferred to the first input of the third multiplexer MX3 and the second node N2. The test enable signal EN transferred to the second node N2 may be transferred to the second input of the third multiplexer MX3 through the interconnect 130 and the first node N1.

The 3b-th circuit 143b may provide the output signal of the node, to which the first circuit 141 and the second circuit 142 are connected, to the 3d-th circuit 143d. The 3b-th circuit 143b may include at least two (e.g., an even number of) inverters for buffering a signal. The 3b-th circuit 143b may output the output signal OUT to the 3d-th circuit 143d. A configuration and an operation of the 3b-th circuit 143b may be the same as those of the 3b-th circuit 143b described with reference to FIG. 2. Thus, additional description will be omitted to avoid redundancy.

The 3d-th circuit 143d may include a plurality of flip-flops. In some example embodiments, the 3d-th circuit 143d may include a first flip-flop FF1, a second flip-flop FF2, a third flip-flop FF3, and a fourth flip-flop FF4. The 3d-th circuit 143d may further include a first delay unit DL1, a second delay unit DL2, and a third delay unit DL3.

A reference voltage Vref may be provided to an input “D” of the first flip-flop FF1 as a first input signal D1. For example, the reference voltage Vref may be provided from the test device 200. The output signal OUT may be provided to a clock input of the first flip-flop FF1. An output “Q” of the first flip-flop FF1 may output a first output signal Q1.

The reference voltage Vref passing through the first delay unit DL1 may be provided to an input “D” of the second flip-flop FF2 as a second input signal D2. The output signal OUT may be provided to a clock input of the second flip-flop FF2. An output “Q” of the second flip-flop FF2 may output a second output signal Q2.

The reference voltage Vref passing through the first delay unit DL1 and the second delay unit DL2 may be provided to an input “D” of the third flip-flop FF3 as a third input signal D3. The output signal OUT may be provided to a clock input of the third flip-flop FF3. An output “Q” of the third flip-flop FF3 may output a third output signal Q3.

The reference voltage Vref passing through the first delay unit DL1, the second delay unit DL2, and the third delay unit DL3 may be provided to an input “D” of the fourth flip-flop FF4 as a fourth input signal D4. The output signal OUT may be provided to a clock input of the fourth flip-flop FF4. An output “Q” of the fourth flip-flop FF4 may output a fourth output signal Q4.

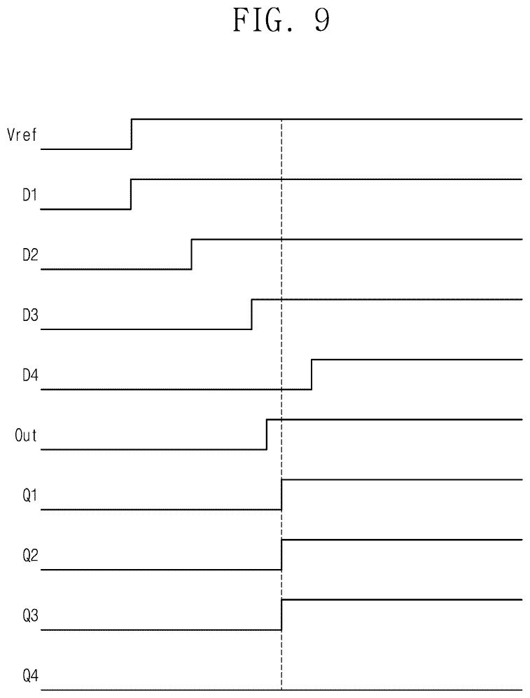

FIG. 9 illustrates an example of a process in which the test circuit 140 of FIG. 8 operates. Referring to FIGS. 1, 8, and 9, as the reference voltage Vref transitions from the low level to the high level under control of the test device 200, the first input signal D1 may transition from the low level to the high level.

After the reference voltage Vref transitions from the low level to the high level, when a time corresponding to the delay amount of the first delay unit DL1 passes, the second input signal D2 may transition from the low level to the high level.

After the reference voltage Vref transitions from the low level to the high level, when a time corresponding to the delay amount of the first delay unit DL1 and the delay amount of the second delay unit DL2 passes, the third input signal D3 may transition from the low level to the high level.

After the reference voltage Vref transitions from the low level to the high level, when a time corresponding to the delay amount of the first delay unit DL1, the delay amount of the second delay unit DL2, and the delay amount of the third delay unit DL3 passes, the fourth input signal D4 may transition from the low level to the high level.

At a given timing, under control of the test device 200, the test enable signal EN may transition from the low level to the high level. After the test enable signal EN transitions from the low level to the high level, when a time corresponding to the delay amount of the first circuit 141, the delay amount of the second circuit 142, and the delay amount of the 3b-th circuit 143b passes (e.g., at a timing marked by a dotted line), the rising edge of the test enable signal EN may be transferred to the clock inputs of the first flip-flop FF1, the second flip-flop FF2, the third flip-flop FF3, and the fourth flip-flop FF4. In response to the rising edge of the test enable signal EN, the first flip-flop FF1, the second flip-flop FF2, the third flip-flop FF3, and the fourth flip-flop FF4 may output current levels of the first input signal D1, the second input signal D2, the third input signal D3, and the fourth input signal D4 as the first output signal Q1, the second output signal Q2, the third output signal Q3, and the fourth output signal Q4.

In some example embodiments, the first flip-flop FF1, the second flip-flop FF2, and the third flip-flop FF3 may output the high levels as the first output signal Q1, the second output signal Q2, and the third output signal Q3, respectively. The fourth flip-flop FF4 may output the low level as the fourth output signal Q4.

For example, because the delay amount of the second circuit 142 is fixed, the first output signal Q1, the second output signal Q2, the third output signal Q3, and the fourth output signal Q4 may include information about how much the test enable signal EN is delayed by the first circuit 141 and the second circuit 142.

The first output signal Q1, the second output signal Q2, the third output signal Q3, and the fourth output signal Q4 may be transferred to the test device 200. The test device 200 may calculate the time constant t based on the first output signal Q1, the second output signal Q2, the third output signal Q3, and the fourth output signal Q4.

In some example embodiments, the test device 200 may calculate the first time constant τ1 described with reference to Equation 2 above, the second time constant τ2 described with reference to Equation 3 above, the third time constant τ3 described with reference to Equation 4 above, and the fourth time constant τ4 described with reference to Equation 5 above. The test device 200 may calculate the first capacitance component Cx1 based on Equation 6 above, the first time constant τ1, the second time constant τ2, the third time constant τ3, and the fourth time constant τ4.

The test device 200 may calculate the fifth time constant τ5 described with reference to Equation 7 above, the sixth time constant τ6 described with reference to Equation 8 above, the seventh time constant τ7 described with reference to Equation 9 above, and the eighth time constant τ8 described with reference to Equation 10 above. The test device 200 may calculate the first resistance component Rx1 based on Equation 11, the fifth time constant τ5, the sixth time constant τ6, the seventh time constant τ7, and the eighth time constant τ8.

An example embodiment in which the test enable signal EN and the reference voltage Vref are signals transitioning from the low level to the high level is described, but example embodiments are not limited thereto and, for example, the test enable signal EN and the reference voltage Vref may be implemented by using a pulse signal which transitions from the low level to the high level and again transitions from the high level to the low level.

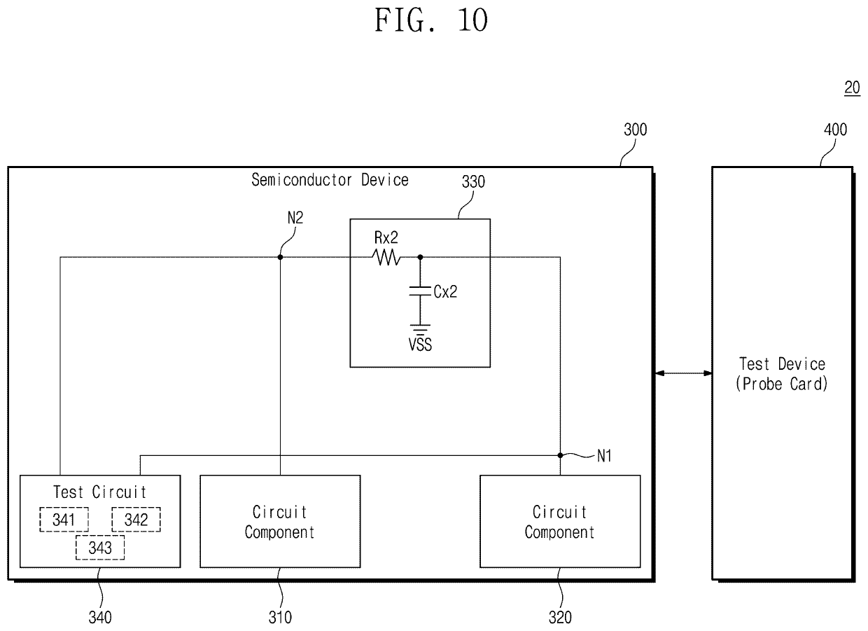

FIG. 10 illustrates a test system 20 of a semiconductor device 300 according to some example embodiments. Referring to FIG. 10, the test system 20 may include the semiconductor device 300 and a test device 400.

The semiconductor device 300 may include various semiconductor devices such as a memory device and a processor device. The test device 400 may include various means for (or the test device 400 may enable) testing the semiconductor device 300, for example, and may include a probe card.

The semiconductor device 300 may include a first circuit component 310, a second circuit component 320, an interconnect 330, and a test circuit 340. The first circuit component 310 and the second circuit component 320 may be configured to perform operations suitable for design purposes of the semiconductor device 300. The interconnect 330 may be configured to electrically connect the first circuit component 310 and the second circuit component 320.

The interconnect 330 may include a second resistance component Rx2 and a second capacitance component Cx2. For example, the second resistance component Rx2 may be based on a parasitic resistance of the interconnect 330. The second resistance component Rx2 may be modeled as a resistor connected in series between the first circuit component 310 and the second circuit component 320. The second capacitance component Cx2 may be based on a parasitic capacitance of the interconnect 330. The second capacitance component Cx2 may be modeled as a capacitor connected in parallel with the ground node, to which the ground voltage VSS is supplied, between the first circuit component 310 and the second circuit component 320.

In some example embodiments, the interconnect 330 may include a horizontal line such as a metal line.

The test circuit 340 may be connected between the first node N1 and the second node N2. The first node N1 may be between the second circuit component 320 and the interconnect 330, and the second node N2 may be between the first circuit component 310 and the interconnect 330. The test circuit 340 may sequentially measure the second resistance component Rx2 and the second capacitance component Cx2, respectively.

The test circuit 340 may include a first circuit 341, a second circuit 342, and a third circuit 343. The first circuit 341 may support the measurement of the second capacitance component Cx2 of the interconnect 330. For example, the first circuit 341 may amplify a signal associated with the second capacitance component Cx2 of the interconnect 330 by providing an additional resistor to the second resistance component Rx2 of the interconnect 330. The first circuit 341 may support to measure the second capacitance component Cx2 more accurately by amplifying the signal associated with the second capacitance component Cx2.

The second circuit 342 may support the measurement of the second resistance component Rx2 of the interconnect 330. For example, the second circuit 342 may amplify a signal associated with the second resistance component Rx2 of the interconnect 330 by providing an additional capacitance to the second capacitance component Cx2 of the interconnect 330. The second circuit 342 may support to measure the second resistance component Rx2 more accurately by amplifying the signal associated with the second resistance component Rx2.

The third circuit 343 may measure the signal associated with the second capacitance component Cx2 and the signal associated with the second resistance component Rx2 and may provide a measurement result to the test device 400.

In some example embodiments, the semiconductor device 100 or the semiconductor device 300 may include at least one vertical interconnect 130 or at least one horizontal interconnect 330. The semiconductor device 100 or the semiconductor device 300 may include the test circuit 140 for testing at least one vertical interconnect 130 or the test circuit 340 for testing at least one horizontal interconnect 330.

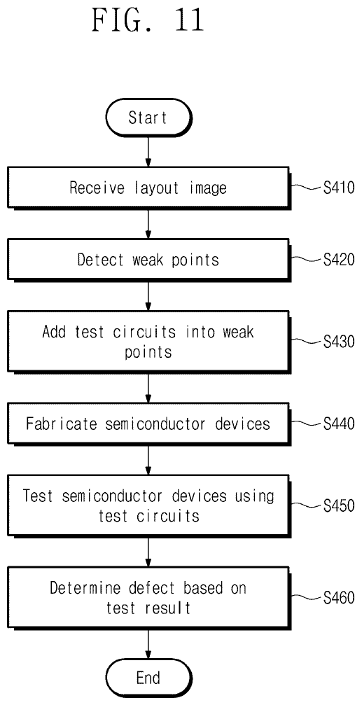

FIG. 11 illustrates an example of a method of implementing the test circuit 140 or the test circuit 340 according to some example embodiments. Referring to FIG. 11, a system for fabrication of the semiconductor device 100 or the semiconductor device 300 may receive a layout image of the semiconductor device 100 or the semiconductor device 300.

In operation S420, the system for fabrication of the semiconductor device 100 or the semiconductor device 300 may detect weak points on the layout. For example, the weak points may include points at which the resistance component or the capacitance component of the interconnect is greater than the threshold value. The system for fabrication of the semiconductor device 100 or the semiconductor device 300 may detect the weak points by using a module trained by using the machine learning or may detect the weak points by using a simulation tool.

In operation S430, the system for fabrication of the semiconductor device 100 or the semiconductor device 300 may add test circuits (e.g., test circuit 140 or test circuit 340) to the weak points. In operation S440, the system for fabrication of the semiconductor device 100 or the semiconductor device 300 may fabricate semiconductor devices based on the layout image. For example, the system for fabrication of the semiconductor device 100 or the semiconductor device 300 may fabricate semiconductor devices in a plurality of dies on a wafer.

In operation S450, the system for fabrication of the semiconductor device 100 or the semiconductor device 300 may test the semiconductor devices by using the test circuits. For example, the system for fabrication of the semiconductor device 100 or the semiconductor device 300 may test the semiconductor device 100 or the semiconductor device 300 depending on (or based on) the method described with reference to FIGS. 1 to 10.

In operation S460, the system for fabrication of the semiconductor device 100 or the semiconductor device 300 may determine the defect based on a test result. In some example embodiments, operation S460 may correspond to operation S130.

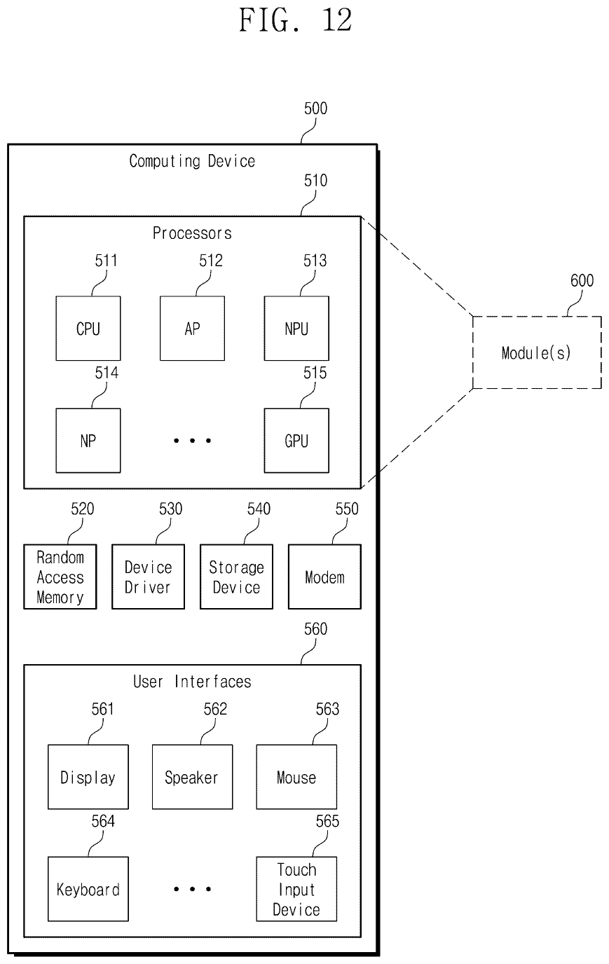

FIG. 12 is a block diagram illustrating an electronic device 500 capable of being a part of a system for fabrication of the semiconductor device 100 or the semiconductor device 300 according to some example embodiments. Referring to FIG. 12, the electronic device 500 may include processors 510, a random access memory 520, a device driver 530, a storage device 540, a modem 550, and user interfaces 560.

The processors 510 may include, for example, at least one general-purpose processor such as a central processing unit (CPU) 511 or an application processor (AP) 512. Additionally or alternatively, the processors 510 may further include at least one special-purpose processor such as a neural processing unit (NPU), a neuromorphic processor (NP), or a graphics processing unit (GPU), but example embodiments are not limited thereto. The processors 510 may include two or more homogeneous processors.

At least one of the processors 510 may be used to train at least one module(s) 600 or to execute the trained module(s) 600. At least one of the processors 510 may train or execute the module(s) 600 based on various data or information. For example, the module(s) 600 may be implemented in the form of instructions (or codes) which are executed by at least one of the processors 510. In some example embodiments, the at least one processor may load the instructions (or codes) of the module(s) 600 to the random access memory 520.

For another example, at least one (or at least another) processor among the processors 510 may be fabricated to implement the module(s) 600. For example, the at least one processor may be a dedicated processor which is implemented in the form of hardware based on the module(s) 600 generated by the learning of the module(s) 600.

For another example, at least one (or at least another) processor among the processors 510 may be fabricated to implement various machine learning or deep learning modules. The at least one processor may implement the module(s) 600 by receiving information (e.g., instructions or codes) corresponding to the module(s) 600.

The random access memory 520 may be used as a working memory of the processors 510 and may be used as a main memory or a system memory of the electronic device 500. The random access memory 520 may include a volatile memory such as a dynamic random access memory or a static random access memory, or a nonvolatile memory such as a phase-change random access memory, a ferroelectric random access memory, a magnetic random access memory, or a resistive random access memory, but example embodiments are not limited thereto.

The device driver 530 may control the following peripheral devices depending on (or based on) a request of the processors 510, the storage device 540, the modem 550, and the user interfaces 560. The storage device 540 may include a stationary storage device such as a hard disk drive or a solid state drive, or a removable storage device such as an external hard disk drive, an external solid state drive, or a removable memory card, but example embodiments are not limited thereto.

The modem 550 may provide remote communication with the external device. The modem 550 may perform wired or wireless communication with the external device. The modem 550 may communicate with the external device based on at least one of various communication schemes such as Ethernet, wireless-fidelity (Wi-Fi), long term evolution (LTE), and 5th generation (5G) mobile communication, but example embodiments are not limited thereto.

The user interfaces 560 may receive information from the user and may provide information to the user. The user interfaces 560 may include at least one user output interface such as a display 561 or a speaker 562, and at least one user input interface such as a mouse 563, a keyboard 564, or a touch input device 565, but example embodiments are not limited thereto.

The instructions (or codes) of the module(s) 600 may be received through the modem 550 and may be stored in the storage device 540. The instructions (or codes) of the module(s) 600 may be stored in a removable storage device, and the removable storage device may be connected to the electronic device 500. The instructions (or codes) of the module(s) 600 may be loaded to the random access memory 520 from the storage device 540 so as to be executed thereon.

In some example embodiments, the module(s) 600 may be configured to perform at least some of the operations described with reference which the FIGS. 1 to 11.

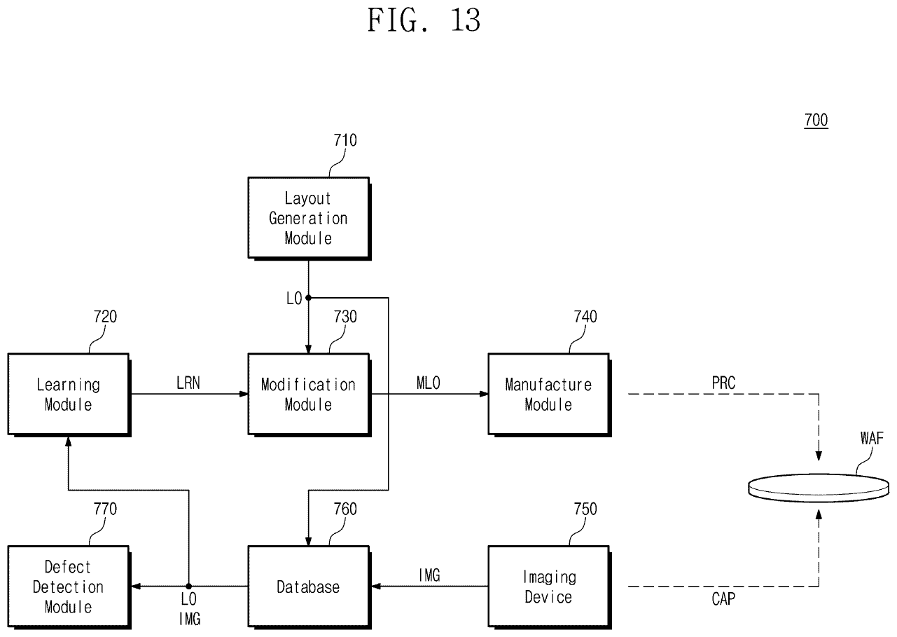

FIG. 13 illustrates a semiconductor fabricating system 700 according to some example embodiments. Referring to FIG. 13, the semiconductor fabricating system 700 may include a layout generation module 710, a learning module 720, a modification module 730, a manufacture device 740, an imaging device 750, a database 760, and a defect detection module 770. The semiconductor fabricating system 700 may fabricate semiconductor devices by using a wafer WAF.

The layout generation module 710 may generate a layout image LO. For example, the layout generation module 710 may generate or receive circuit-based design information. The layout generation module 710 may generate the layout image LO by placing standard cells based on the design information. Alternatively or additionally, after placing the standard cells, the layout generation module 710 may generate the layout image LO by modifying the standard cells or placing specialization cells, which are not included in the standard cells, under control of the user. For example, the layout image LO which the layout generation module 710 generates may be a new layout image LO for fabrication of new semiconductor devices.

The learning module 720 may perform learning LRN of the modification module 730. For example, the learning module 720 may generate and update the modification module 730 based on the machine learning. The learning module 720 may perform the learning LRN based on various machine learning algorithms such as a neural network and a generative adversarial network (GAN), but example embodiments are not limited thereto.

The learning module 720 may receive the layout image LO (or a modified layout image MLO) and a captured image IMG from the database 760. The layout image LO may be an image of an initial layer for fabrication of a semiconductor device. The captured image IMG may be an image generated by capturing a semiconductor device fabricated based on the layout image LO (or the modified layout image MLO). For example, the learning module 720 may perform the learning LRN of the modification module 730 based on a pre-image of a fabricated semiconductor device (e.g., the layout image LO for fabrication of a semiconductor device or the modified layout image MLO) and a post-image (e.g., the captured image IMG after fabrication of a semiconductor device).

The modification module 730 may be trained by the learning module 720. The modification module 730 may receive the layout image LO for fabrication of new semiconductor devices from the layout generation module 710. In some example embodiments, the modification module 730 may be trained to generate the modified layout image MLO from the layout image LO.

The modification module 730 may be trained to generate the modified layout image MLO from the layout image LO based on various factors capable of being caused in the process of fabricating semiconductor devices, for example, the modification module 730 may be trained to generate the modified layout image MLO based at least on a process proximity correction (PPC) and an optical proximity correction (OPC).

For example, the optical proximity correction may be performed to correct distortions caused in photoresist patterns due to various factors, which include a characteristic of a light source, a characteristic of a photoresist, positional relationships between the light source and patterns formed in the photoresist, etc., in the process of generating a photomask for fabrication of semiconductor devices. The process proximity correction may be used to correct distortions caused during processes (e.g., an etching process) due to various factors including characteristics of materials for performing a process, characteristics of materials to which the process is applied, characteristics of photoresist patterns, etc.

The manufacture device 740 may receive the modified layout image MLO from the modification module 730. The manufacture device 740 may apply processes PRC to the wafer WAF based on the modified layout image MLO. For example, the processes PRC may include an etching process, a deposition process, a growth process, a planarization process, etc. As the processes PRC are applied to the wafer WAF, semiconductor devices may be formed in the wafer WAF.

The imaging device 750 may generate the captured image IMG by capturing an image of the semiconductor devices formed in the wafer WAF (e.g., refer to “CAP” of FIG. 1). For example, the imaging device 750 may include a scanning electron microscope (SEM).

The database 760 may receive the layout image LO from the layout generation module 710 and may receive the captured image IMG of the semiconductor devices fabricated based on the layout image LO from the imaging device 750. The database 760 may store and manage the layout image LO and the captured image IMG in pairs (or in a correspondence relationship).

The defect detection module 770 may receive the layout image LO and the corresponding captured image IMG from the database 760. The defect detection module 770 may detect defects of the semiconductor devices by comparing the layout image LO and the captured image IMG. For example, the defect detection module 770 may detect defects of the semiconductor devices by comparing a pre-image (e.g., the layout image LO) and a post-image (e.g., the captured image IMG) of the semiconductor devices.

In some example embodiments, the defect detection module 770 may correspond to the test device 200 or the test device 400. The defect detection module 770 may interact with test devices of semiconductor devices fabricated on the wafer WAF to detect resistance components and capacitance components of weak points. In some example embodiments, when the resistance component or the capacitance component is greater than the threshold value, the defect detection module 770 may determine the defect.

The learning module 720 may further receive the layout image LO and the captured image IMG used for fabrication of the semiconductor devices from the database 760 and may perform learning. Additionally or alternatively, the learning module 720 may be configured to perform the learning for inferring the weak points.

In some example embodiments, the layout generation module 710, the learning module 720, the modification module 730, and the defect detection module 770 may be implemented with software executable by a processor, a processor designed to perform a relevant function, or a combination of hardware and software designed to a relevant function.

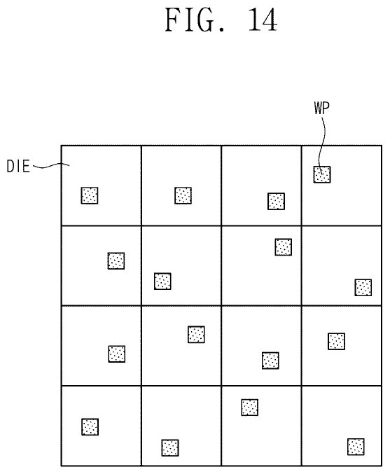

FIG. 14 illustrates an example of weak points WP of semiconductor dies DIE on the wafer WAF. In some example embodiments, locations of the weak points WP of the semiconductor dies DIE may be identical to or different from each other in the semiconductor dies DIE. In some example embodiments, the locations of the weak points WP are illustrated in FIG. 14 as being different from each other in the semiconductor dies DIE.

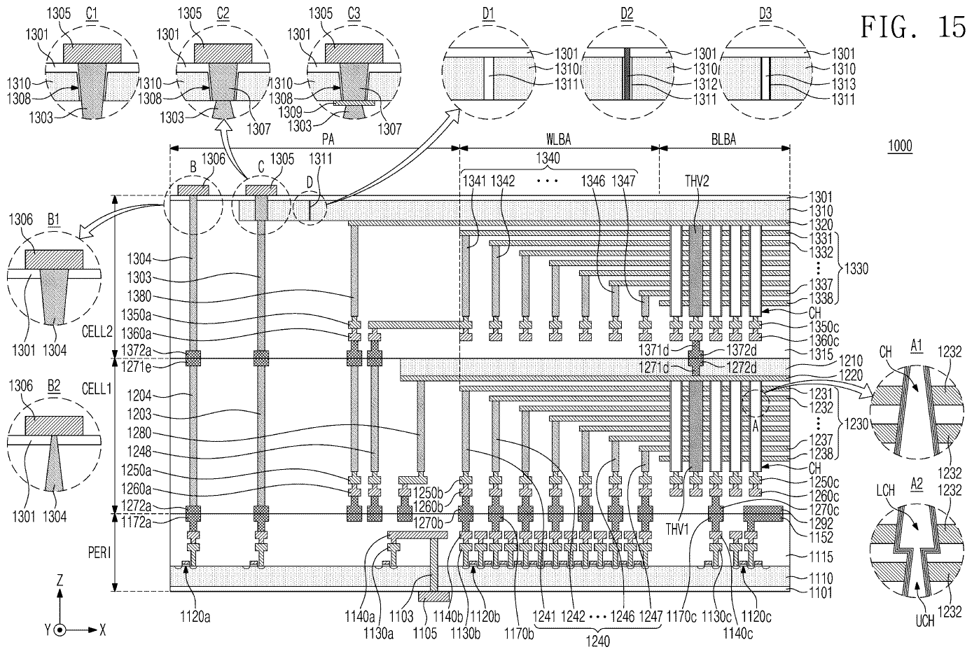

FIG. 15 is a view for describing a semiconductor device 1000 according to some example embodiments. Referring to FIG. 15, the semiconductor device 1000 may have a chip-to-chip (C2C) structure. Herein, in the C2C structure, after fabricating at least one upper chip including a cell region CELL and at least one lower chip including a peripheral circuit region PERI, respectively, the upper chip and the lower chip may be bonded to each other by a bonding method. For example, the bonding method may mean a method of electrically or physically connecting a bonding metal pattern formed in the uppermost metal layer of the upper chip and a bonding metal pattern formed in the uppermost metal layer of the lower chip. For example, when the bonding metal patterns are formed of copper (Cu), the bonding method may be referred to as a “Cu—Cu bonding method”. As another example, the bonding metal patterns may also be formed of aluminum (Al) or tungsten (W), but example embodiments are not limited thereto.

The semiconductor device 1000 may include at least one upper chip including a cell region. For example, as illustrated in FIG. 15, the semiconductor device 1000 may be implemented to include two upper chips. However, this is illustrative, and the number of upper chips is not limited thereto. In the case in which the semiconductor device 1000 is implemented to include two upper chips, the semiconductor device 1000 may be fabricated by separately fabricating a first upper chip including a first cell region CELL1, a second upper chip including a second cell region CELL2, and a lower chip including the peripheral circuit region PERI and thereafter connecting the first upper chip, the second upper chip, and the lower chip by a bonding method. The first upper chip may be turned over and connected to the lower chip by the bonding method, and the second upper chip may also be turned over and connected to the first upper chip by the bonding method. In the following description, upper portions and lower portions of the first and second upper chips are defined based on before the first upper chip and the second upper chip are turned over. For example, in FIG. 15, an upper portion of the lower chip refers to an upper portion defined based on a +Z-axis direction, and the upper portions of the first and second upper chips refer to upper portions defined based on a −Z-axis direction. However, this is illustrative, and only one of the first upper chip and the second upper chip may be turned over and connected by the bonding method.

Each of the peripheral circuit region PERI and the first and second cell regions CELL1 and CELL2 of the semiconductor device 1000 may include an external pad bonding region PA, a word line bonding region WLBA, and a bit line bonding region BLBA.

The peripheral circuit region PERI may include a first substrate 1110 and a plurality of circuit elements 1120a, 1120b, and 1120c formed on the first substrate 1110. An interlayer insulating layer 1115 including one or more insulating layers may be provided on the plurality of circuit elements 1120a, 1120b, and 1120c, and a plurality of metal lines connecting the plurality of circuit elements 1120a, 1120b, and 1120c may be provided in the interlayer insulating layer 1115. For example, the plurality of metal lines may include first metal lines 1130a, 1130b, and 1130c connected with the plurality of circuit elements a 1120a, 1120b, and 1120c, respectively, and second metal lines 1140a, 1140b, and 1140c formed on the first metal lines 1130a, 1130b, and 1130c. The plurality of metal lines may be formed of at least one of various conductive materials. For example, the first metal lines 1130a, 1130b, and 1130c may be formed of tungsten having a relatively high electrical resistivity, and the second metal lines 1140a, 1140b, and 1140c may be formed of copper having a relatively low electrical resistivity, but example embodiments are not limited thereto.

In this specification, only the first metal lines 1130a, 1130b, and 1130c and the second metal lines 1140a, 1140b, and 1140c are illustrated and described. However, without being limited thereto, one or more additional metal lines may be further formed on the second metal lines 1140a, 1140b, and 1140c. In some example embodiments, the second metal lines 1140a, 1140b, and 1140c may be formed of aluminum. At least some of the additional metal lines formed on the second metal lines 1140a, 1140b, and 1140c may be formed of copper having a lower electrical resistivity than the aluminum of the second metal lines 1140a, 1140b, and 1140c.

The interlayer insulating layer 1115 may be disposed on the first substrate 1110 and may include an insulating material, such as silicon oxide or silicon nitride, but example embodiments are not limited thereto.

Each of the first and second cell regions CELL1 and CELL2 may include at least one memory block. The first cell region CELL1 may include a second substrate 1210 and a common source line 1220. A plurality of word lines 1231 to 1238 (hereinafter collectively referred to as “1230”) may be stacked on the second substrate 1210 in a direction (e.g., the Z-axis direction) perpendicular to an upper surface of the second substrate 1210. String selection lines and a ground selection line may be disposed on and under the word lines 1230, and the plurality of word lines 1230 may be disposed between the string selection lines and the ground selection line. Likewise, the second cell region CELL2 may include a third substrate 1310 and a common source line 1320, and a plurality of word lines 1331 to 1338 (hereinafter collectively referred to as “1330”) may be stacked in a direction (e.g., the Z-axis direction) perpendicular to an upper surface of the third substrate 1310. The second substrate 1210 and the third substrate 1310 may be formed of various materials and may be, for example, silicon substrates, silicon-germanium substrates, germanium substrates, or substrates having mono-crystalline epitaxial layers grown on mono-crystalline silicon substrates, but example embodiments are not limited thereto. A plurality of channel structures CH may be formed in the first and second cell regions CELL1 and CELL2.

In some example embodiments, as illustrated in A1, the channel structure CH may be provided in the bit line bonding region BLBA and may extend in the direction perpendicular to the upper surface of the second substrate 1210 to penetrate the word lines 1230, the string selection lines, and the ground selection line. The channel structure CH may include a data storage layer, a channel layer, and a buried insulating layer. The channel layer may be electrically connected with a first metal line 1250c and a second metal line 1260c in the bit line bonding region BLBA. For example, the second metal line 1260c may be a bit line and may be connected to the channel structure CH through the first metal line 1250c. The bit line 1260c may extend in a first direction (e.g., a Y-axis direction) parallel to the upper surface of the second substrate 1210.

In some example embodiments, as illustrated in A2, the channel structure CH may include a lower channel LCH and an upper channel UCH connected to each other. For example, the channel structure CH may be formed through a process for the lower channel LCH and a process for the upper channel UCH. The lower channel LCH may extend in the direction perpendicular to the upper surface of the second substrate 1210 and may penetrate the common source line 1220 and the lower word lines 1231 and 1232. The lower channel LCH may include a data storage layer, a channel layer, and a buried insulating layer and may be connected with the upper channel UCH. The upper channel UCH may penetrate the upper word lines 1233 to 1238. The upper channel UCH may include a data storage layer, a channel layer, and a buried insulating layer, and the channel layer of the upper channel UCH may be electrically connected with the first metal line 1250c and the second metal line 1260c. As the length of a channel is increased, it may be difficult to form a channel having a constant width due to process reasons. The semiconductor device 1000 according to some example embodiments may include a channel having improved width uniformity through the lower channel LCH and the upper channel UCH formed by sequential processes.

In the case in which the channel structure CH includes the lower channel LCH and the upper channel UCH as illustrated in A2, a word line located near the boundary between the lower channel LCH and the upper channel UCH may be a dummy word line. For example, the word line 1232 and the word line 1233 that form the boundary between the lower channel LCH and the upper channel UCH may be dummy word lines. In some example embodiments, data may not be stored in memory cells connected to the dummy word lines. Alternatively or additionally, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

Meanwhile, it is illustrated in A2 that the number of lower word lines 1231 and 1232 penetrated by the lower channel LCH is smaller than the number of upper word lines 1233 to 1238 penetrated by the upper channel UCH. However, this is illustrative, and example embodiments are not limited thereto. In another example, the number of lower word lines penetrated by the lower channel LCH may be equal to or larger than the number of upper word lines penetrated by the upper channel UCH. Furthermore, the above-described structure and connection relationship of the channel structure CH disposed in the first cell region CELL1 may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 15, the first through-electrode THV1 may penetrate the common source line 1220 and the plurality of word lines 1230. However, this is illustrative, and the first through-electrode THV1 may additionally penetrate the second substrate 1210. The first through-electrode THV1 may include a conductive material. Alternatively or additionally, the first through-electrode THV1 may include a conductive material surrounded by an insulating material. The second through-electrode THV2 may have the same shape and structure as the first through-electrode THV1.

In some example embodiments, the first through-electrode THV1 and the second through-electrode THV2 may be electrically connected through a first through-metal pattern 1272d and a second through-metal pattern 1372d. The first through-metal pattern 1272d may be formed on a lower side of the first upper chip including the first cell region CELL1, and the second through-metal pattern 1372d may be formed on an upper side of the second upper chip including the second cell region CELL2. The first through-electrode THV1 may be electrically connected with the first metal line 1250c and the second metal line 1260c. A lower VIA 1271d may be formed between the first through-electrode THV1 and the first through-metal pattern 1272d, and an upper VIA 1371d may be formed between the second through-electrode THV2 and the second through-metal pattern 1372d. The first through-metal pattern 1272d and the second through-metal pattern 1372d may be connected by a bonding method.

Furthermore, in the bit line bonding region BLBA, an upper metal pattern 1152 may be formed on the uppermost metal layer of the peripheral circuit region PERI, and an upper metal pattern 1292 having the same shape as the upper metal pattern 1152 may be formed on the uppermost metal layer of the first cell region CELL1. The upper metal pattern 1292 of the first cell region CELL1 and the upper metal pattern 1152 of the peripheral circuit region PERI may be electrically connected to each other by a bonding method. In the bit line bonding region BLBA, the bit line 1260c may be electrically connected with a page buffer included in the peripheral circuit region PERI. For example, some of the circuit elements 1120c of the peripheral circuit region PERI may provide a page buffer, and the bit line 1260c may be electrically connected with the circuit elements 1120c providing the page buffer through an upper bonding metal 1270c of the first cell region CELL1 and an upper bonding metal 1170c of the peripheral circuit region PERI.

Continuously referring to FIG. 15, in the word line bonding region WLBA, the word lines 1230 of the first cell region CELL1 may extend in a second direction (e.g., an X-axis direction) parallel to the upper surface of the second substrate 1210 and may be connected with a plurality of cell contact plugs 1241 to 1247 (hereinafter collectively referred to as “1240”). A first metal line 1250b and a second metal line 1260b may be sequentially connected to upper portions of the cell contact plugs 1240 connected to the word lines 1230. In the word line bonding region WLBA, the cell contact plugs 1240 may be connected with the peripheral circuit region PERI through an upper bonding metal 1270b of the first cell region CELL1 and an upper bonding metal 1170b of the peripheral circuit region PERI.

The cell contact plugs 1240 may be electrically connected with a row decoder included in the peripheral circuit region PERI. For example, some of the circuit elements 1120b of the peripheral circuit region PERI may provide a row decoder, and the cell contact plugs 1240 may be electrically connected with the circuit elements 1120b providing the row decoder through the upper bonding metal 1270b of the first cell region CELL1 and the upper bonding metal 1170b of the peripheral circuit region PERI. In some example embodiments, an operating voltage of the circuit elements 1120b that provide the row decoder may differ from an operating voltage of the circuit elements 1120c that provide the page buffer. For example, the operating voltage of the circuit elements 1120c that provide the page buffer may be greater than the operating voltage of the circuit elements 1120b that provide the row decoder.

Likewise, in the word line bonding region WLBA, the word lines 1330 of the second cell region CELL2 may extend in the second direction (e.g., the X-axis direction) parallel to the upper surface of the third substrate 1310 and may be connected with a plurality of cell contact plugs 1341 to 1347 (hereinafter collectively referred to as “1340”). The cell contact plugs 1340 may be connected with the peripheral circuit region PERI through an upper metal pattern of the second cell region CELL2, a lower metal pattern and an upper metal pattern of the first cell region CELL1, and a cell contact plug 1248.

In the word line bonding region WLBA, the upper bonding metal 1270b may be formed in the first cell region CELL1, and the upper bonding metal 1170b may be formed in the peripheral circuit region PERI. The upper bonding metal 1270b of the first cell region CELL1 and the upper bonding metal 1170b of the peripheral circuit region PERI may be electrically connected to each other by a bonding method. The upper bonding metal 1270b and the upper bonding metal 1170b may be formed of aluminum, copper, or tungsten, but example embodiments are not limited thereto.

In the external pad bonding region PA, a lower metal pattern 1271e may be formed on a lower portion of the first cell region CELL1, and an upper metal pattern 1372a may be formed on an upper portion of the second cell region CELL2. The lower metal pattern 1271e of the first cell region CELL1 and the upper metal pattern 1372a of the second cell region CELL2 may be connected by a bonding method in the external pad bonding region PA. Likewise, an upper metal pattern 1272a may be formed on an upper portion of the first cell region CELL1, and an upper metal pattern 1172a may be formed on an upper portion of the peripheral circuit region PERI. The upper metal pattern 1272a of the first cell region CELL1 and the upper metal pattern 1172a of the peripheral circuit region PERI may be connected to each other by a bonding method.

Common source line contact plugs 1280 and 1380 may be disposed in the external pad bonding region PA. The common source line contact plugs 1280 and 1380 may be formed of a conductive material, such as metal, a metal compound, or doped poly-silicon, but example embodiments are not limited thereto. The common source line contact plug 1280 of the first cell region CELL1 may be electrically connected with the common source line 1220, and the common source line contact plug 1380 of the second cell region CELL2 may be electrically connected with the common source line 1320. A first metal line 1250a and a second metal line 1260a may be sequentially stacked on an upper portion of the common source line contact plug 1280 of the first cell region CELL1, and a first metal line 1350a and a second metal line 1360a may be sequentially stacked on an upper portion of the common source line contact plug 1380 of the second cell region CELL2.

Input/output pads 1105, 1305, and 1306 may be disposed in the external pad bonding region PA. Referring to FIG. 15, a lower insulating layer 1101 may cover a lower surface of the first substrate 1110, and the first input/output pad 1105 may be formed on the lower insulating layer 1101. The first input/output pad 1105 may be connected with at least one of the plurality of circuit elements 1120a disposed in the peripheral circuit region PERI through a first input/output contact plug 1103 and may be separated from the first substrate 1110 by the lower insulating layer 1101. Additionally or alternatively, a side insulating layer may be disposed between the first input/output contact plug 1103 and the first substrate 1110 and may electrically isolate the first input/output contact plug 1103 from the first substrate 1110.

An upper insulating layer 1301 may be formed on the third substrate 1310 to cover the upper surface of the third substrate 1310. The second input/output pad 1305 and/or the third input/output pad 1306 may be disposed on the upper insulating layer 1301. The second input/output pad 1305 may be connected with at least one of the plurality of circuit elements 1120a disposed in the peripheral circuit region PERI through second input/output contact plugs 1303 and 1203, and the third input/output pad 1306 may be connected with at least one of the plurality of circuit elements 1120a disposed in the peripheral circuit region PERI through third input/output contact plugs 1304 and 1204.

In some example embodiments, the third substrate 1310 may not be disposed in the regions in which the input/output contact plugs are disposed. For example, as illustrated in B, the third input/output contact plug 1304 may be separated from the third substrate 1310 in a direction parallel to the upper surface of the third substrate 1310, may penetrate an interlayer insulating layer 1315 of the second cell region CELL2, and may be connected to the third input/output pad 1306. In some example embodiments, the third input/output contact plug 1304 may be formed through various processes.

For example, as illustrated in B1, the third input/output contact plug 1304 may extend in the third direction (e.g., the Z-axis direction) and may have an increasing diameter toward the upper insulating layer 1301. For example, while the channel structure CH described with reference to A1 has a decreasing diameter toward the upper insulating layer 1301, the third input/output contact plug 1304 may have an increasing diameter toward the upper insulating layer 1301. For example, the third input/output contact plug 1304 may be formed after the second cell region CELL2 and the first cell region CELL1 are coupled by a bonding method.

For example, as illustrated in B2, the third input/output contact plug 1304 may extend in the third direction (e.g., the Z-axis direction) and may have a decreasing diameter toward the upper insulating layer 1301. For example, likewise to the channel structure CH, the third input/output contact plug 1304 may have a decreasing diameter toward the upper insulating layer 1301. For example, the third input/output contact plug 1304 may be formed together with the cell contact plugs 1340 before the second cell region CELL2 and the first cell region CELL1 are coupled by a bonding method.

In some example embodiments, an input/output contact plug may be disposed to overlap the third substrate 1310. For example, as illustrated in C, the second input/output contact plug 1303 may be formed through the interlayer insulating layer 1315 of the second cell region CELL2 in the third direction (e.g., the Z-axis direction) and may be electrically connected to the second input/output pad 1305 through the third substrate 1310. In some example embodiments, a connection structure of the second input/output contact plug 1303 and the second input/output pad 1305 may be implemented in various ways.

For example, as illustrated in C1, an opening 1308 may be formed through the third substrate 1310, and the second input/output contact plug 1303 may be directly connected to the second input/output pad 1305 through the opening 1308 formed in the third substrate 1310. In some example embodiments, as illustrated in C1, the second input/output contact plug 1303 may have an increasing diameter toward the second input/output pad 1305. However, this is illustrative, and the second input/output contact plug 1303 may have a decreasing diameter toward the second input/output pad 1305.

For example, as illustrated in C2, the opening 1308 may be formed through the third substrate 1310, and a contact 1307 may be formed in the opening 1308. One end portion of the contact 1307 may be connected to the second input/output pad 1305, and an opposite end portion of the contact 1307 may be connected to the second input/output contact plug 1303. Accordingly, the second input/output contact plug 1303 may be electrically connected to the second input/output pad 1305 through the contact 1307 in the opening 1308. In some example embodiments, as illustrated in C2, the contact 1307 may have an increasing diameter toward the second input/output pad 1305, and the second input/output contact plug 1303 may have a decreasing diameter toward the second input/output pad 1305. For example, the third input/output contact plug 1304 may be formed together with the cell contact plugs 1340 before the second cell region CELL2 and the first cell region CELL1 are coupled by a bonding method, and the contact 1307 may be formed after the second cell region CELL2 and the first cell region CELL1 are coupled by the bonding method.

For example, as illustrated in C3, a stopper 1309 may be additionally formed on an upper surface of the opening 1308 of the third substrate 1310. The stopper 1309 may be a metal line formed on the same layer as the common source line 1320. However, this is illustrative, and the stopper 1309 may be a metal line formed on the same layer as at least one of the word lines 1330. The second input/output contact plug 1303 may be electrically connected to the second input/output pad 1305 through the contact 1307 and the stopper 1309.

Meanwhile, similarly to the second and third input/output contact plugs 1303 and 1304 of the second cell region CELL2, the second and third input/output contact plugs 1203 and 1204 of the first cell region CELL1 may have a decreasing diameter toward the lower metal pattern 1271e, or may have an increasing diameter toward the lower metal pattern 1271e.

Meanwhile, in some example embodiments, a slit 1311 may be formed in the third substrate 1310. For example, the slit 1311 may be formed at any position in the external pad bonding region PA. For example, as illustrated in D, the slit 1311 may be located between the second input/output pad 1305 and the cell contact plugs 1340 when viewed on a plane. However, this is illustrative, and the slit 1311 may be formed such that the second input/output pad 1305 is located between the slit 1311 and the cell contact plugs 1340 when viewed on the plane.

For example, as illustrated in D1, the slit 1311 may be formed through the third substrate 1310. For example, the slit 1311 may be used to prevent the third substrate 1310 from being finely cracked when the opening 1308 is formed (or to reduce a probability/chance of the third substrate 1310 from being cracked when the opening 1308 is formed). However, this is illustrative, and the slit 1311 may be formed to have a depth ranging from about 60% to about 70% of the thickness of the third substrate 1310, but example embodiments are not limited thereto.

For example, as illustrated in D2, a conductive material 1312 may be formed in the slit 1311. For example, the conductive material 1312 may be used to discharge a leakage current generated while circuit elements in the external pad bonding region PA are driven. In some example embodiments, the conductive material 1312 may be connected to an external ground line.

For example, as illustrated in D3, an insulating material 1313 may be formed in the slit 1311. For example, the insulating material 1313 may be formed to electrically isolate the second input/output pad 1305 and the second input/output contact plug 1303 disposed in the external pad bonding region PA from the word line bonding region WLBA. An influence of a voltage provided through the second input/output pad 1305 on a metal layer disposed on the third substrate 1310 in the word line bonding region WLBA may be interrupted by forming the insulating material 1313 in the slit 1311.

Meanwhile, in some example embodiments, the first to third input/output pads 1105, 1305, and 1306 may be selectively formed. For example, the semiconductor device 1000 may be implemented to include only the first input/output pad 1105 disposed on the first substrate 1110, only the second input/output pad 1305 disposed on the third substrate 1310, or only the third input/output pad 1306 disposed on the upper insulating layer 1301.

Meanwhile, in some example embodiments, at least one of the second substrate 1210 of the first cell region CELL1 or the third substrate 1310 of the second cell region CELL2 may be used as a sacrificial substrate and may be completely or partially removed before or after a bonding process. An additional layer may be stacked after the removal of the substrate. For example, the second substrate 1210 of the first cell region CELL1 may be removed before or after the peripheral circuit region PERI and the first cell region CELL1 are bonded to each other, and an insulating layer for covering an upper surface of the common source line 1220 or a conductive layer for connection may be formed. Similarly, the third substrate 1310 of the second cell region CELL2 may be removed before or after the first cell region CELL1 and the second cell region CELL2 are bonded to each other, and the upper insulating layer 1301 for covering an upper surface of the common source line 1320 or a conductive layer for connection may be formed.

As described with reference to FIG. 15, the semiconductor device 1000 may include a relatively long vertical interconnect THV1 or a relatively long vertical interconnect THV2. The resistance component or the capacitance component of the vertical interconnect THV1 or the vertical interconnect THV2 may affect the operating characteristic of the semiconductor device 1000. The test device 200 or the test device 400 according to some example embodiments may detect the defect of the semiconductor device 1000 by measuring the resistance component or the capacitance component of the vertical interconnect THV1 or the vertical interconnect THV2.

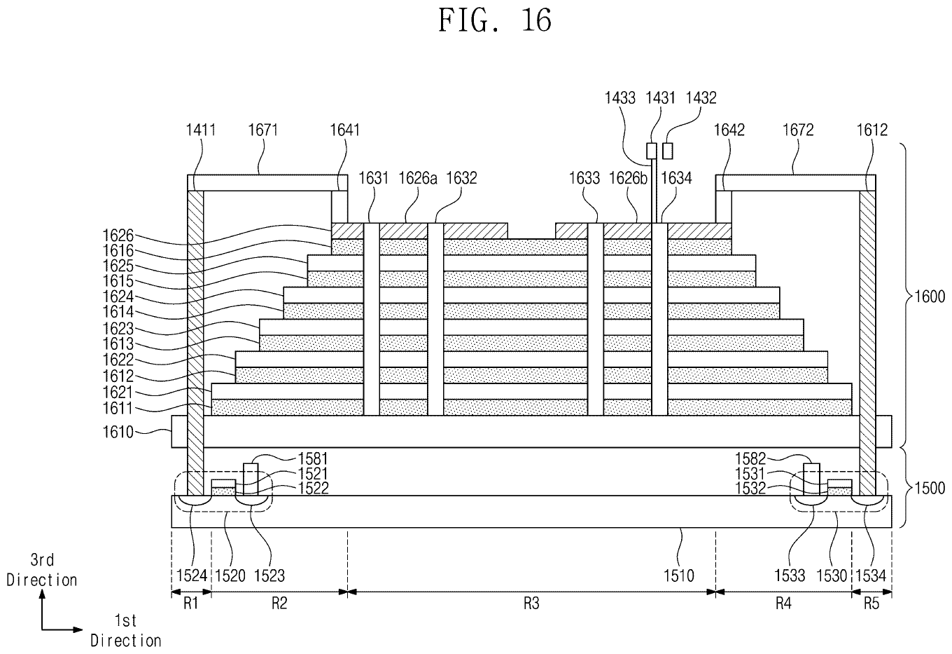

FIG. 16 illustrates an example in which the semiconductor device 100 or the semiconductor device 300 is fabricated in a COP method. Referring to FIGS. 16, the semiconductor device 100 or the semiconductor device 300 may include a peripheral circuit 1500 and a cell structure 1600 on the peripheral circuit 1500. For example, the semiconductor device 100 or the semiconductor device 300 may include the cell over peri (COP) structure.

The peripheral circuit 1500 may include a first active region 1510, and elements 1520 and elements 1530 on the first active region 1510. The first active region 1510 may be formed in a semiconductor substrate. The elements 1520 and elements 1530 may include the first pass transistor 1520 and the second pass transistor 1530, respectively.

The first pass transistor 1520 may include a gate 1521, an insulating layer 1522, a first junction 1523, and a second junction 1524. The second pass transistor 1530 may include a gate 1531, an insulating layer 1532, a first junction 1533, and a second junction 1534.

The first junction 1523 of the first pass transistor 1520 may be connected to a first peripheral circuit via 1581. The first peripheral circuit via 1581 may be connected to a line (or a wire) which is not illustrated. The second junction 1524 of the first pass transistor 1520 may be connected to a first through via 1411. For example, the first through via 1411 may be a through hole via (THV).

The first junction 1533 of the second pass transistor 1530 may be connected to a second peripheral circuit via 1582. The second peripheral circuit via 1582 may be connected to a line (or a wire) which is not illustrated. The second junction 1534 of the second pass transistor 1530 may be connected to a second through via 1612. For example, the second through via 1412 may be a through hole via (THV).

The gate 1521 of the first pass transistor 1520 and the gate 1531 of the second pass transistor 1530 may be connected to a common line (e.g., one of lower metal lines of lower metal layers). The first peripheral circuit via 1581 and the second peripheral circuit via 1582 may be connected to a common line (e.g., one of the lower metal lines of the lower metal layers).

For example, the first pass transistor 1520 and the second pass transistor 1530 may operate in response to a common control signal, the first pass transistor 1520 may transfer a common voltage of the common line to the first through via 1411, and the second pass transistor 1530 may transfer the common voltage to the second through via 1412.

In some example embodiments, only elements connected to the first through via 1411 and the second through via 1412 from among elements constituting the components of the peripheral circuit 1500 are illustrated in FIG. 16. Additional components that are not illustrated in FIG. 16 may be added to the peripheral circuit 1500.

First to fifth regions R1 to R5 may be defined along a first direction depending on (or based on) features of components of the cell structure 1600. However, the definition of the first to fifth regions R1 to R5 is provided for convenience of description, but example embodiments are not limited thereto.

The cell structure 1600 may include a second active region 1610 and a vertical structure on the second active region 1610. The vertical structure may include a pair of a first insulating layer 1611 and a first conductive layer 1621, a pair of a second insulating layer 1612 and a second conductive layer 1622, a pair of a third insulating layer 1613 and a third conductive layer 1623, a pair of a fourth insulating layer 1614 and a fourth conductive layer 1624, and a pair of a fifth insulating layer 1615 and a fifth conductive layer 1625.

A pair of a sixth insulating layer 1616 and a sixth conductive layer 1626 may be provided on the vertical structure. The sixth conductive layer 1626 may include a first partial conductive layer 1626a and a second partial conductive layer 1626b that are spaced from each other to face each other in the first direction. The first partial conductive layer 1626a and the second partial conductive layer 1626b may be spaced apart from each other along the first direction such that the sixth insulating layer 1616 under the sixth conductive layer 1626 is exposed.

In the third region R3, first to fourth vertical channels 1631 to 1634 may penetrate the sixth conductive layer 1626, the sixth insulating layer 1616, and the vertical structure in a third direction.

In some example embodiments, an information storage layer including a silicon oxide layer, a silicon nitride layer, and a silicon oxide layer may be formed between the first to sixth conductive layers 1621 to 1626 and the first to fourth vertical channels 1631 to 1634.

In the second region R2 and the fourth region R4, the pairs of the first to sixth insulating layers 1611 to 1616 and the first to sixth conductive layers 1621 to 1626 may have lengths (e.g., lengths in the first direction) which stepwise decrease along the third direction.

In the first region R1, the first through via 1411 may penetrate the second active region 1610 and may extend in the third direction. The first through via 1411 may be connected to a first memory cell via 1641, which is on a first conductive layer in the first direction from among conductive layers included in the first partial conductive layer 1626a, through a first upper conductive layer 1671. The first upper conductive layer 1671 may be one of upper metals of an upper metal layer.

As in the first through via 1411, a through via which is connected to each of the first to fifth conductive layers 1621 to 1625 through a relevant pass transistor of the peripheral circuit 1500, a relevant upper conductive layer, and a relevant partial conductive layer may be provided in the first region R1.

In the fifth region R5, the second through via 1612 may penetrate the second active region 1610 and may extend in the third direction. The second through via 1612 may be connected to a second memory cell via 1642, which is on a first conductive layer in the second direction from among conductive layers included in the second partial conductive layer 1626b, through a second upper conductive layer 1672. The second upper conductive layer 1672 may be one of the upper metals of the upper metal layer.

As in the second through via 1612, a through via which is connected to each of the first to fifth conductive layers 1621 to 1625 through a relevant pass transistor of the peripheral circuit 1500, a relevant upper conductive layer, and a relevant partial conductive layer may be provided in the first region R5.

In the third region R3, conductive lines (e.g., some of metal lines of upper metal layers) may be provided on/over the sixth conductive layer 1626. To prevent a drawing from being unnecessarily complicated (or to reduce complexity of a drawing), two conductive lines, for example, first and second conductive lines 1431 and 1432, respectively, are illustrated as an example. The first conductive line 1431 and the second conductive line 1432 may extend in the second direction. The first conductive line 1431 may be connected to the fourth vertical channel 1634 through a conductive line via 1433.

The first through via 1411 and the second through via 1612 may be a relatively long vertical interconnect. The resistance component or the capacitance component of the vertical interconnect may affect the operating characteristic of the semiconductor device 100 or the semiconductor device 300. The test device 200 or the test device 400 according to some example embodiments may detect the defect of the semiconductor device 100 or the semiconductor device 300 by measuring the resistance component or the capacitance component of the vertical interconnect.

Example embodiments in which the semiconductor device 100 or the semiconductor device 300 is implemented are described in detail with reference to FIGS. 15 and 16. However, example embodiments in which the semiconductor device 100 or the semiconductor device 300 is implemented are not limited to those described with reference to FIGS. 15 and 16. Example embodiments may be extensively applied semiconductor devices including a vertical or horizontal interconnect.

In the above example embodiments, components are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

In the above example embodiments, components according to example embodiments of inventive concepts are referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP).

According to some example embodiments, a semiconductor device may include resistors, capacitors, and multiplexers for testing resistance components and capacitance components of interconnects. The semiconductor device may amplify the resistance components and the capacitance components of the interconnects by using the resistors and the capacitors and may independently measure the resistance components and the capacitance components. Accordingly, a semiconductor device providing a means for (or a semiconductor device may enable) independently measuring the resistance components and the capacitance components of the interconnects of the semiconductor device and a method of testing the semiconductor device are provided.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

While the present inventive concepts have been described with reference to some example embodiments thereof, it will be apparent to those of ordinary skill in the art that various changes and modifications may be made thereto without departing from the spirit and scope of the present inventive concepts as set forth in the following claims.

What is claimed is:

1. A semiconductor device comprising:
a first circuit component;
a second circuit component;
an interconnect configured to electrically connect the first circuit component and the second circuit component; and
a test circuit connected between the first circuit component and the interconnect, and between the second circuit component and the interconnect,
wherein the test circuit is configured to measure a resistance component and a capacitance component of the interconnect.

2. The semiconductor device of claim 1, wherein the test circuit is configured to sequentially measure the resistance component and the capacitance component.

3. The semiconductor device of claim 1, wherein the test circuit is configured to measure the resistance component with an external test device including a reference resistor.

4. The semiconductor device of claim 3, wherein the test circuit is configured to:
measure a first time constant based on the reference resistor and a first capacitance; and
measure a second time constant based on the reference resistor and a second capacitance.

5. The semiconductor device of claim 4, wherein the test circuit is configured to:
measure a third time constant based on the interconnect and the first capacitance; and
measure a fourth time constant based on the interconnect and the second capacitance.

6. The semiconductor device of claim 5, wherein the test circuit is configured to measure the resistance component of the interconnect based on the first time constant, the second time constant, the third time constant, and the fourth time constant.

7. The semiconductor device of claim 1, wherein the test circuit is configured to measure the capacitance component with an external test device including a reference capacitance.

8. The semiconductor device of claim 7, wherein the test circuit is configured to:
measure a first time constant based on the reference capacitance and a first resistor; and
measure a second time constant based on the reference capacitance and a second resistor.

9. The semiconductor device of claim 8, wherein the test circuit is configured to:
measure a third time constant based on the interconnect and the first resistor; and
measure a fourth time constant based on the interconnect and the second resistor.

10. The semiconductor device of claim 9, wherein the test circuit is configured to measure the capacitance component of the interconnect based on the first time constant, the second time constant, the third time constant, and the fourth time constant.

11. The semiconductor device of claim 1, wherein the test circuit includes:
a logic gate configured to provide a first signal to a first terminal of the interconnect; and
a first multiplexer configured to output one of the first signal and a second signal corresponding to the first signal transferred through the interconnect.

12. The semiconductor device of claim 11, wherein the test circuit further includes:
a second multiplexer configured to select one of a reference resistor, a first resistor, and a second resistor, and
wherein the first resistor and the second resistor are connected in series with an output of the first multiplexer, the reference resistor is provided from an external test device, and the reference resistor is connected in series with the first multiplexer.

13. The semiconductor device of claim 12, wherein the test circuit further includes:
a third multiplexer configured to select one of a reference capacitor, a first capacitor, and a second capacitor, and
wherein the first capacitor and the second capacitor are connected in parallel with an output of the second multiplexer, the reference capacitor is provided from the external test device, and the reference capacitor is connected in parallel with the second multiplexer.

14. The semiconductor device of claim 13, wherein the test circuit further includes:
delay units configured to delay a third signal output from the third multiplexer to the logic gate,
wherein the logic gate includes a NAND gate, and
wherein a delay amount of the delay units is determined based on an operating frequency of the external test device.

15. The semiconductor device of claim 1, wherein the test circuit includes:
a first multiplexer configured to output one of a first signal provided to a first terminal of the interconnect and a second signal corresponding to the first signal transferred through the interconnect.

16. The semiconductor device of claim 15, wherein the test circuit further includes:
a second multiplexer configured to select one of a reference resistor, a first resistor, and a second resistor, wherein the first resistor and the second resistor are connected in series with an output of the first multiplexer, the reference resistor is provided from an external test device, and the reference resistor is connected in series with the first multiplexer; and
a third multiplexer configured to select one of a reference capacitor, a first capacitor, and a second capacitor, wherein the first capacitor and the second capacitor are connected in parallel with an output of the second multiplexer, the reference capacitor is provided from the external test device, and the reference capacitor is connected in parallel with the second multiplexer.

17. The semiconductor device of claim 16, wherein the test circuit further includes:
a plurality of flip-flops,
wherein each flip-flop of the plurality of flip-flops includes,
an input node to which a reference voltage is transferred; and
a clock node to which an output of the third multiplexer is transferred.

18. The semiconductor device of claim 17, wherein the test circuit further includes:
a plurality of delay units, and
wherein the plurality of delay units are configured to delay a change in the reference voltage to be transferred to input nodes of the plurality of flip-flops, respectively.

19. A method of testing a semiconductor device including an interconnect connecting circuit components and a test circuit connected to the interconnect, the method comprising:
calculating a first time constant using a first capacitance of the test circuit and a reference resistor of an external test device;
calculating a second time constant using a second capacitance of the test circuit and the reference resistor of the external test device;
calculating a third time constant using the first capacitance of the test circuit and the interconnect;
calculating a fourth time constant using the second capacitance of the test circuit and the interconnect; and
calculating a resistance component of the interconnect based on the first time constant, the second time constant, the third time constant, and the fourth time constant.

20. A method of testing a semiconductor device including an interconnect connecting circuit components and a test circuit connected to the interconnect, the method comprising:
calculating a first time constant using a first resistor of the test circuit and a reference capacitance of an external test device;
calculating a second time constant using a second resistor of the test circuit and the reference capacitance of the external test device;
calculating a third time constant using the first resistor of the test circuit and the interconnect;
calculating a fourth time constant using the second resistor of the test circuit and the interconnect; and
calculating a capacitance component of the interconnect based on the first time constant, the second time constant, the third time constant, and the fourth time constant.
